(19) United States
(12) Patent Application Publication
(10) Pub. No.: US 2026/0064905 A1
(43) Pub. Date: Mar. 5, 2026

(54) ORBIT PROPAGATION SIMULATION OF SATELLITE SYSTEM

(71) Applicant: WILDSTAR, LLC, Saratoga, CA (US)

(72) Inventor: Amirebrahim Darabi, San Francisco, CA (US)

(73) Assignee: WILDSTAR, LLC, Saratoga, CA (US)

(21) Appl. No.: 18/798,269

(22) Filed: Aug. 8, 2024

Related U.S. Application Data
(60) Provisional application No. 63/636,855, filed on Apr. 21, 2024.

(51) Int. Cl. G06F 30/20

(52) U.S. Cl. CPC G06F 30/20

(57) ABSTRACT

The disclosed technology is generally directed to a method for simulating orbit propagation of a satellite system including a constellation of satellites. In one example of the technology, the method may include receiving an input indicating whether to simulate the orbit propagation for a single satellite or a plurality of satellites of the constellation, and a set of orbital parameters associated with each satellite. Based on the input and the set of orbital parameters: simulating the orbit propagation of the single satellite or the plurality of satellites to iteratively determine a velocity and a position of the single satellite or the plurality of satellites. The method may include iteratively storing the velocity and the position in a buffer and dynamically rendering a user interface to display a visualization representing the orbit propagation of one of the single satellite and the plurality of satellites.

### CROSS REFERENCE TO RELATED APPLICATIONS

This application claims the benefit of U.S. Provisional Application Ser. No. 63/636,855, filed on Apr. 22, 2024, the disclosure of which is incorporated herein by reference.

### TECHNICAL FIELD

This disclosure is directed to simulation of a satellite system, and more particularly, to simulation of orbit propagation of the satellite system.

### BACKGROUND

Satellites have become important tools for various applications, including communication, Earth observation, navigation, and scientific research. The design and operation of the satellites require meticulous planning and analysis to ensure mission success and longevity in space environments. When planning for complexities of space missions, satellite simulation is important with an aim to evaluate performance at a system level. Space mission modelling using simulation is developing rapidly alongside the complex challenges of today and tomorrow's space missions. Simulation software has become an important tool for satellite engineers and researchers, allowing them to model and analyze satellite behavior under different operating conditions.

Satellite orbit propagation is an important aspect of space missions, enabling precise determination of positions and velocities of the satellites. Orbit propagation corresponds to predictive determination of a location of the satellite with respect to the Earth and the Sun. Determining the orbit propagation of a satellite or a constellation of satellites is an important simulation step. Traditional methods for the satellite orbit propagation rely on numerical integration techniques based on Newtonian mechanics or Keplerian orbital elements. While the traditional methods have served as the foundation for orbit prediction, they exhibit limitations in accuracy, computational efficiency, and robustness, particularly in the presence of environmental perturbations and complex mission scenarios.

Traditional methods for the satellite simulation often rely on manual calculations with limited functionality. These approaches may lack the accuracy, flexibility, and scalability needed to address the complexities of modern satellite systems. In recent years, there has been a growing demand for advanced simulation software capable of accurately modeling the behavior of the satellites in a wide range of scenarios. Such software enables engineers, researchers, and mission planners to simulate satellite orbits, predict orbital maneuvers, optimize mission parameters, and analyze system performance in a virtual environment.

Several commercial and open-source software packages exist for the satellite modeling and simulation, including Systems Tool Kit (STK), Orekit, General Mission Analysis Tool (GMAT), and FreeFlyer. While these tools offer valuable capabilities for simulating the satellite dynamics and mission planning, they may suffer from limitations such as complexity, accuracy, performance, and integration challenges.

Therefore, in light of the foregoing, there is a need for a technical solution to overcome the challenges associated with conventional systems for satellite simulation.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one aspect, an exemplary embodiment of the present disclosure may provide a method for simulating orbit propagation of a satellite system including a constellation of satellites. Implementations of the described techniques may include hardware, a method or process, or a non-transitory, a computer readable medium, etc. Other embodiments of this aspect include corresponding computer systems, apparatus, and computer programs recorded on one or more computer storage devices, each configured to perform the actions of the methods. The system may include one or more computers that can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. Implementations may include one or more of the following features.

The method may include receiving an input indicating whether to simulate the orbit propagation for one of a single satellite of the constellation of satellites and a plurality of satellites of the constellation of satellites. Further, receiving a set of orbital parameters associated with each satellite of the constellation of satellites. When the input indicates to simulate the orbit propagation for the single satellite: simulating the orbit propagation of the single satellite to determine a velocity and a position of the single satellite with respect to the Earth and the Sun based on the set of orbital parameters. The velocity and the position of the single satellite are iteratively determined by repeating the simulating of the orbit propagation of the single satellite as the single satellite traverses through a respective orbit of that single satellite. When the input indicates to simulate the orbit propagation for the plurality of satellites: simulating, via a parallel processor, the orbit propagation of each of the plurality of satellites in parallel to determine a velocity and a position of each satellite of the plurality of satellites with respect to the Earth and the Sun based on the set of orbital parameters. The velocity and the position of each satellite of the plurality of satellites are iteratively determined by repeating the simulating of the orbit propagation for each satellite of the plurality of satellites as each satellite of the plurality of satellites traverse through a respective orbit of that satellite. Further, the method may include iteratively storing the velocity and the position of one of the single satellite and each of the plurality of satellites in a buffer after the simulating of the orbit propagation of one of the single satellite and the plurality of satellites. Furthermore, the method may include dynamically rendering a user interface to display a visualization representing the orbit propagation of one of the single satellite and the plurality of satellites based on the simulating of the orbit propagation of one of the single satellite and each of the plurality of satellites. Other embodiments of this aspect include corresponding computer systems, apparatus, and computer programs recorded on one or more computer storage devices, each configured to perform the actions of the methods.

Implementations may include one or more of the following features. In some implementations, the set of orbital parameters may include at least one of an inclination angle, an angle between propagating planes, an altitude of the satellite, a number of propagating planes, an angle of a starting plane, a number of satellites in the constellation of satellites, a number of satellites per plane, a number of orbit period, a timestep per period, a simulation timestep, a beam angle, a day and time of launch, and a simulation period.

In some implementations, the set of orbital parameters are input based on an interaction with the user interface rendered on a computing device.

In some implementations, the velocity and the position are iteratively determined when the user modifies the set of parameters.

In some implementations, the method may further include utilizing the velocity and the position of one of the single satellite and each of the plurality of satellites and a set of link budget parameters to simulate link budgets for one of the single satellite and the constellation of satellites.

In some implementations, the method may further include utilizing the velocity and the position of one of the single satellite and each of the plurality of satellites and a set of power analysis parameters to simulate power analysis for one of the single satellite and the constellation of satellites.

In some implementations, the method may further include utilizing the velocity and the position of one of the single satellite and each of the plurality of satellites and a set of light pollution parameters to simulate light pollution for one of the single satellite and the constellation of satellites.

In some implementations, the method may further include utilizing the velocity and the position of one of the single satellite and each of the plurality of satellites and a set of orientation parameters to simulate controlling of an orientation of one of the single satellite and the constellation of satellites to stabilize one of the single satellite and the constellation of satellites.

In some implementations, the method may further include utilizing the velocity and the position of one of the single satellite and each of the plurality of satellites and a set of heat transfer parameters to simulate heat transfer for one of the single satellite and the constellation of satellites.

In some implementations, the visualization may correspond to at least one of: a two-dimensional plot, a three-dimensional model of the Earth, and a two-dimensional contour.

In another aspect, an exemplary embodiment of the present disclosure may provide a system for simulating orbit propagation of a satellite system comprising a constellation of satellites. The system includes at least one hardware-based processor and memory. The memory comprises processor-executable instructions encoded on a non-transient processor-readable media. The processor-executable instructions, when executed by the at least one hardware-based processor, configure the system to receive an input indicating whether to simulate the orbit propagation for one of a single satellite of the constellation of satellites and a plurality of satellites of the constellation of satellites and receive a set of orbital parameters associated with each satellite of the constellation of satellites. When the input indicates to simulate the orbit propagation for the single satellite, the processor-executable instructions, when executed by the at least one hardware-based processor, further configure the system to simulate the orbit propagation of the single satellite to determine, based on the set of orbital parameters, a velocity and a position of the single satellite with respect to the Earth and the Sun. The velocity and the position of the single satellite are iteratively determined by repeating the simulating of the orbit propagation of the single satellite as the single satellite traverses through a respective orbit of that single satellite. Further, when the input indicates to simulate the orbit propagation for the plurality of satellites, the processor-executable instructions, when executed by the at least one hardware-based processor, further configure the system to simulate, via a parallel processor, the orbit propagation of each of the plurality of satellites in parallel to determine, based on the set of orbital parameters, a velocity and a position of each satellite of the plurality of satellites with respect to the Earth and the Sun. The velocity and the position of each satellite of the plurality of satellites are iteratively determined by repeating the simulating of the orbit propagation for each satellite of the plurality of satellites as each satellite of the plurality of satellites traverse through a respective orbit of that satellite. Additionally, the processor-executable instructions, when executed by the at least one hardware-based processor, further configure the system to iteratively store the velocity and the position of one of the single satellite and each of the plurality of satellites in a buffer after the simulating of the orbit propagation of one of the single satellite and the plurality of satellites and dynamically render a user interface to display a visualization representing the orbit propagation of one of the single satellite and the plurality of satellites based on the simulating of the orbit propagation of one of the single satellite and each of the plurality of satellites.

In yet another aspect, an exemplary embodiment of the present disclosure may provide a non-transitory computer-readable medium storing a set of instructions for simulating orbit propagation of a satellite system comprising a constellation of satellites. The set of instructions comprising one or more instructions that, when executed by one or more processors of a device, cause the device to receive an input indicating whether to simulate the orbit propagation for one of a single satellite of the constellation of satellites and a plurality of satellites of the constellation of satellites and receive a set of orbital parameters associated with each satellite of the constellation of satellites. When the input indicates to simulate the orbit propagation for the single satellite, the one or more instructions that, when executed by the one or more processors of a device, further cause the device to simulate the orbit propagation of the single satellite to determine, based on the set of orbital parameters, a velocity and a position of the single satellite with respect to the Earth and the Sun. The velocity and the position of the single satellite are iteratively determined by repeating the simulating of the orbit propagation of the single satellite as the single satellite traverses through a respective orbit of that single satellite. Further, when the input indicates to simulate the orbit propagation for the plurality of satellites, the one or more instructions that, when executed by the one or more processors of a device, further cause the device to simulate, via a parallel processor, the orbit propagation of each of the plurality of satellites in parallel to determine, based on the set of orbital parameters, a velocity and a position of each satellite of the plurality of satellites with respect to the Earth and the Sun. The velocity and the position of each satellite of the plurality of satellites are iteratively determined by repeating the simulating of the orbit propagation for each satellite of the plurality of satellites as each satellite of the plurality of satellites traverse through a respective orbit of that satellite. Additionally, the one or more instructions that, when executed by the one or more processors of a device, further cause the device to iteratively store the velocity and the position of one of the single satellite and each of the plurality of satellites in a buffer after the simulating of the orbit propagation of one of the single satellite and the plurality of satellites and dynamically render a user interface to display a visualization representing the orbit propagation of one of the single satellite and the plurality of satellites based on the simulating of the orbit propagation of one of the single satellite and each of the plurality of satellites.

Further aspects, features, applications, and advantages of the disclosed technology, as well as the structure and operation of various examples, are described in detail below with reference to the accompanying drawings. It is noted that the disclosed technology is not limited to the specific examples described herein. Such examples are presented herein for illustrative purposes only. Additional examples will be apparent to persons skilled in the relevant art(s) based on the teachings contained herein.

### BRIEF DESCRIPTION OF THE SEVERAL VIEWS OF THE DRAWINGS

For a better understanding of the present disclosure, non-limiting and non-exhaustive examples of the present disclosure are described with reference to the following drawings, in which:

FIG. 1 is a block diagram illustrating a system environment for simulating a satellite system in which aspects of the technology may be employed;

FIG. 2A is a block diagram illustrating an application server of FIG. 1 in which aspects of the technology may be employed;

FIG. 2B is a block diagram illustrating a parallel processor of FIG. 2A in which aspects of the technology may be employed;

FIG. 3 is a block diagram illustrating an orbit propagation subsystem of FIG. 2B in which aspects of the technology may be employed;

FIG. 4 is a block diagram that illustrates an exemplary user interface rendered on a computing device in which aspects of the technology may be practiced;

FIGS. 5A-5D are diagrams that represent exemplary user interfaces rendered on the computing device in which aspects of the technology may be practiced;

FIGS. 6A and 6B, collectively, illustrate a flow chart of a method for simulating orbit propagation of the satellite system according to aspects of the disclosed technology;

FIG. 7 is a block diagram illustrating a link budget subsystem of FIG. 2B in which aspects of the technology may be employed;

FIG. 8 is a block diagram that illustrates an exemplary user interface rendered on the computing device in which aspects of the technology may be practiced;

FIGS. 9A-9D are diagrams that represent exemplary user interfaces rendered on the computing device in which aspects of the technology may be practiced;

FIGS. 10A and 10B, collectively, illustrate a flow chart of a method for simulating link budget of the satellite system according to aspects of the disclosed technology;

FIG. 11 is a block diagram illustrating a power analysis subsystem of FIG. 2B in which aspects of the technology may be employed;

FIG. 12 is a block diagram that illustrates an exemplary user interface rendered on the computing device in which aspects of the technology may be practiced;

FIGS. 13A-13D are diagrams that represent exemplary user interfaces rendered on the computing device in which aspects of the technology may be practiced;

FIG. 14 illustrates a flow chart of a method for simulating power analysis of at least one satellite according to aspects of the disclosed technology;

FIG. 15 illustrates a flow chart of a method for simulating power analysis of each satellite of a constellation of satellites according to aspects of the disclosed technology; and

FIG. 16 is a diagram illustrating one example of computing device in which aspects of the technology may be practiced.

In the drawings, similar reference numerals refer to similar parts throughout the drawings unless otherwise specified. These drawings are not necessarily drawn to scale.

### DETAILED DESCRIPTION

Technologies are provided for simulation of a satellite system. Technologies are also provided for simulating orbit propagation of the satellite system. The specification and accompanying drawings disclose one or more exemplary embodiments that incorporate the features of the present disclosure. The scope of the present disclosure is not limited to the disclosed embodiments. The disclosed embodiments merely exemplify the present disclosure, and modified versions of the disclosed embodiments are also encompassed by the present disclosure. Embodiments of the present disclosure are defined by the claims appended hereto.

It is noted that any section/subsection headings provided herein are not intended to be limiting. Any embodiments described throughout this specification, and disclosed in any section/subsection may be combined with any other embodiments described in the same section/subsection and/or a different section/subsection in any manner.

Implementations of the techniques described herein may include hardware, a method or process, or a non-transitory computer readable medium, etc. Other embodiments of this aspect include corresponding computer systems, apparatus, and computer programs recorded on one or more computer storage devices, each configured to perform the actions of the methods. The system may include one or more computers that can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. Implementations may include one or more of the following features. Prior to describing exemplary embodiments that incorporate the features of the present disclosure, a discussion of security concepts that are applicable to the exemplary embodiments will be provided.

Satellites are important components for various applications, including communication, Earth observation, and scientific research, but precise control and stability of the satellites is important for their functionality and longevity. The functions primarily involve managing satellite orbits, controlling orientation (attitude) of the satellites, and ensuring stability against external forces. As used herein, the term “attitude” refers to the orientation or position of the satellite with respect to a reference frame, typically the celestial sphere or the Earth. The attitude of a satellite describes how the satellite is pointed in space and is characterized by its angular position along three principal axes called the roll axis, pitch axis and yaw axis. Attitude may be specified using a set of Euler angles or direction cosines that define how the satellite is oriented in three-dimensional space. These angles describe the rotations needed to transform the satellite's coordinate system to a fixed reference frame, such as the Earth-centered inertial frame.

Additionally, the satellites may need to perform maneuvers, maintain safety, and support continuous communication with ground terminals and/or other satellites. Technological advancements in satellite control and stabilization systems may enhance or improve the reliability and performance in various tasks, from telecommunications to space exploration and scientific research.

Utilization of satellite simulation may improve such satellite control systems by enabling accurate orbit prediction, autonomous maneuvers, real-time attitude control, anomaly detection, efficient communication, collision avoidance, predictive maintenance, resource management, mission planning, and space weather prediction. Satellite simulation driven advancements may optimize satellite operations, extend their lifespan, improve data collection, enhance communication efficiency, ensure safety, and enable proactive maintenance, contributing to the overall effectiveness of satellites in applications ranging from telecommunications to Earth observation and space exploration.

Technical Problem with Conventional Satellite Simulation Technologies

In the field of the satellite simulation, traditional methods face an array of complex technical challenges that have become increasingly pronounced in modern satellite systems. Traditional methods for the satellite simulation include complex mathematical models based on orbital mechanics, dynamics, and environmental factors. Implementing and solving the complex mathematical models may be challenging, requiring specialized knowledge and computational resources. Traditional methods are built for specific applications or scenarios, limiting their flexibility to adapt to different mission requirements or satellite configurations. Traditional simulation software packages fail to comprehensively simulate many problems and issues related to operation of satellite(s) in a single simulation software package.

Additionally, traditional methods may struggle to scale up to simulate large satellite constellations or complex mission scenarios. As the number of satellites or simulation parameters increase, computational resources and simulation runtimes may become prohibitive. Integrating traditional simulation tools with other software systems or workflows may be difficult. Lack of interoperability and standardized data formats may require manual data conversion or custom integration efforts, leading to inefficiencies and errors. The traditional methods may lack advanced visualization and analysis features, making it challenging for users to interpret simulation results effectively.

Integrating real-world data, such as satellite ephemerides, atmospheric conditions, or sensor measurements, into the traditional methods may be challenging. Traditional methods are complex and require specialized knowledge to use effectively and hence, users may need to invest significant time and effort in learning how to use the software, which can be a barrier for newcomers to the field. Traditional methods lack storing previous simulation results during simulation and hence a user has to start the simulation from scratch each time they run the simulation.

In accordance with the disclosed embodiments, a system environment is provided that may be used to simulate most, if not all, problems related to modelling operation and performance of a single satellite and/or a constellation of satellites in the space. Calculations can be implemented using parallel computing and a vectorization technique, which is optimized to rapidly perform the calculations in parallel to deliver real-time or near real-time output results. The system environment provides the option to communicate with matrix laboratory (MATLAB) to import and export data for further analysis. Further, the system environment is a user friendly environment and is easy to use. Furthermore, the system environment is embedded with a satellite attitude control and a sensor fusion based on machine learning. Additionally, the system environment includes storing of simulation results and the previously stored results are used further for subsequent simulations.

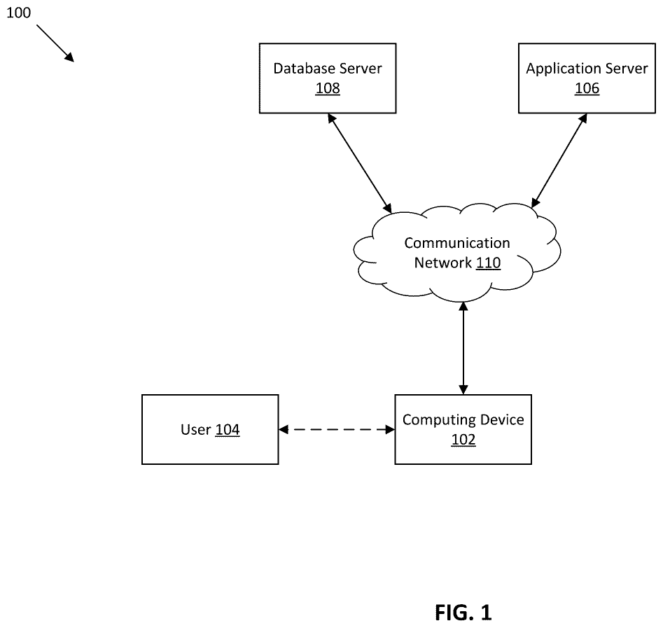

Having given this description of the system environment for the satellite simulation that can be applied within the context of the present disclosure, technologies will now be described for simulating orbit propagation, link budget, light pollution, power analysis, heat transfer, and controlling of an orientation of the satellite system based on various parameters of the satellite system will now be described with reference to FIGS. 1-16.

FIG. 1 is a block diagram illustrating a system environment 100 for simulating a satellite system in which aspects of the technology may be employed. The satellite system may include at least one satellite or may correspond to a constellation of satellites. The system environment 100 includes a computing device 102, a user 104, an application server 106, and a database server 108. The computing device 102, the application server 106, and the database server 108 may be coupled to each other via a communication network 110.

The computing device 102 may include suitable logic, circuitry, interfaces, and/or code, executable by the circuitry, that may be configured to perform one or more operations. The one or more operations may be performed by utilizing the service application running on the computing device 102. The service application may be associated with a simulation software and hosted by application server 106. In an embodiment, the computing device 102 may be utilized by the user 104 to input a set of parameters associated with the satellite system to simulate the satellite system within the simulation software. Further, the computing device 102 may be utilized, by the user 104, for interacting with a user interface so as to provide one or more inputs for initiating the one or more operations associated with the simulation of the satellite system.

Additionally, the computing device 102 may be utilized, by the user 104, to view the user interface rendered on the computing device 102. Various modes of input that may be utilized, by the user 104, to input the set of parameters include, but are not limited to, a touch-based input, a text-based input, a voice-based input, a gesture-based input, or a combination thereof. Examples of the computing device 102 may include, but are not limited to, a personal computer, a laptop, a smartphone, and a tablet computer.

The user 104 is an individual, such as satellite engineers, researchers, mission planners, and the like, who may want to perform simulation of the satellite system utilizing the system environment 100. The user 104 may initiate simulation of the satellite system by inputting the set of parameters associated with the satellite system. In one embodiment, the simulation of the satellite system may be initiated, by the user 104, by utilizing the service application running on the computing device 102.

The application server 106 may include suitable logic, circuitry, interfaces, and/or code, executable by the circuitry, that may be configured to perform one or more operations for simulation of the satellite system. The application server 106 may be a computing device, which may include a software framework that may be configured to create the application server 106 implementation and perform the various operations associated with simulation of the satellite system.

The application server 106 may be realized through various web-based technologies, such as, but are not limited to, a Java web-framework, a .NET framework, a PHP framework, a python framework, or any other web-application framework. The application server 106 may also be realized as a machine-learning model that implements any suitable machine-learning techniques, statistical techniques, or probabilistic techniques. Examples of such techniques may include expert systems, fuzzy logic, support vector machines (SVM), Hidden Markov models (HMMs), greedy search algorithms, rule-based systems, Bayesian models (e.g. Bayesian networks), neural networks, decision tree learning methods, other non-linear training techniques, data fusion, utility-based analytical systems, or the like. Examples of the application server 106 may include, but are not limited to, a personal computer, a laptop, or a network of computer systems.

In an embodiment, the application server 106 may be configured to process, control, and manage various functionalities and operations such as user authentication, reception of the set of parameters, simulation, visualization, and the like. For example, the application server 106 may be further configured to receive user credentials that includes a username and a password of the user 104 to authenticate the user 104 from the computing device 102 via the communication network 110. Upon successful authentication of the user 104, the application server 106 may be configured to receive a set of orbital parameters from the computing device 102 via the communication network 110. Further, the application server 106 may be configured to receive a selection input from the computing device 102 via the communication network 110 whether to simulate one of link budget, light pollution, power analysis, heat transfer, and controlling of an orientation of the satellite system according to the selection by the user 104 on the computing device 102.

When the selection input indicates simulation of the link budget, the application server 106 may be configured to receive a set of link budget parameters. When the selection input indicates simulation of the light pollution, the application server 106 may be configured to receive a set of light pollution parameters. When the selection input indicates simulation of the power analysis, the application server 106 may be configured to receive a set of power analysis parameter. When the selection input indicates simulation of the heat transfer, the application server 106 may be configured to receive a set of heat transfer parameters. When the selection input indicates simulation of the controlling of the orientation of the satellite system, the application server 106 may be configured to receive a set of orientation parameters. The application server 106 may be further configured to import a set of databases and information from the database server 108 for simulation of the satellite system.

Further, the application server 106 may be configured to simulate orbit propagation of the satellite system based on the set of orbital parameters. Additionally, the application server 106 may be configured to simulate one of the link budget, the light pollution, the power analysis, the heat transfer, and the controlling of the orientation of the satellite system based on the selection input and respective parameters, respective databases received or imported by the application server 106.

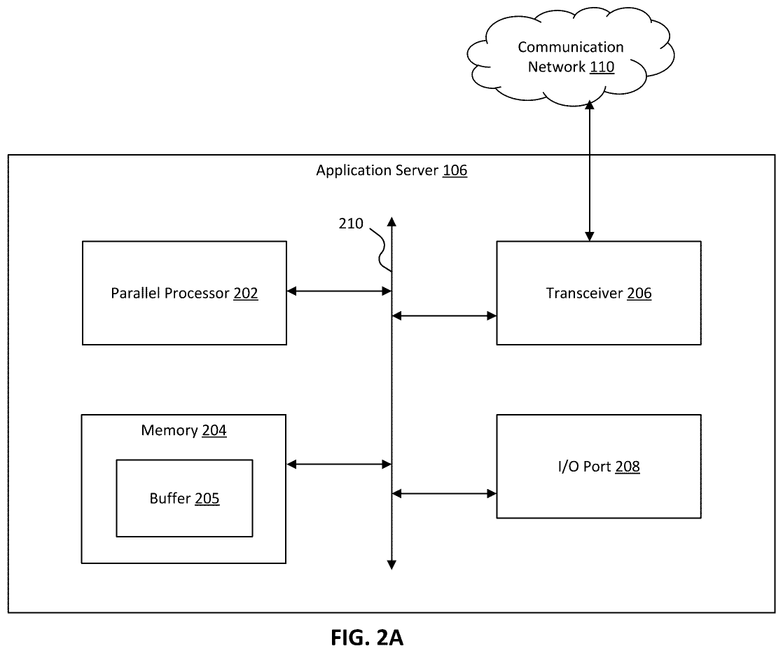

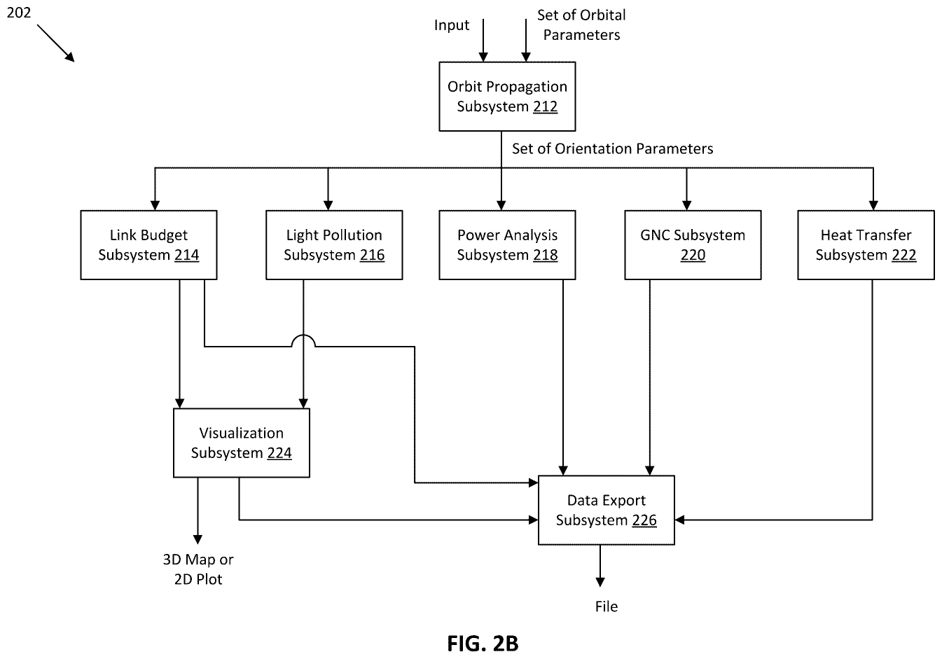

The application server 106 may be further configured to display a visualization representing the orbit propagation of the satellite system. In an embodiment, the visualization corresponds to at least one of a two-dimensional plot, a three-dimensional model of the Earth, and a two-dimensional contour through the user interface rendered on the computing device 102 via the communication network 110. Additionally, along with the visualization representing the orbit propagation of the satellite system, the application server 106 may be configured to display a visualization representing one of the link budget, the light pollution, the power analysis, the heat transfer, and the controlling of the orientation of the satellite system according to the selection input. Various operations and functionalities of the application server 106 have been described in detail in conjunction with FIGS. 2-16.

The database server 108 may include suitable logic, circuitry, interfaces, and/or code, executable by the circuitry, that may be configured to perform one or more database operations, such as receiving, storing, processing, and transmitting data, or content. The database server 108 may be a data management and storage computing device that is communicatively coupled to the computing device 102, and the application server 106 via the communication network 110 to perform the one or more database operations. Examples of the database server 108 may include, but are not limited to, a personal computer, a laptop, or a network of computer systems.

The database server 108 may be further configured to store a set of databases comprising a first database and a second database. The first database includes country borders information, ocean borders information, and shipping lanes information. The second database includes a plurality of point of interests on the Earth.

The database server 108 may be configured to transmit the first database to the application server 106 via the communication network 110 to determine the location of a user equipment during simulation of the link budget The database server 108 may be configured to transmit the second database to the application server 106 via the communication network 110 to determine the number of satellites in the satellite system. Various operations of the database server 108 have been described in detail in conjunction with FIGS. 2-16.

The communication network 110 may include suitable logic, circuitry, interfaces, and/or code, executable by the circuitry, that may be configured to transmit messages, and requests between various entities, such as the computing device 102, the application server 106, and/or the database server 108. Examples of the communication network 110 include, but are not limited to, a wireless fidelity (Wi-Fi) network, a light fidelity (Li-Fi) network, a local area network (LAN), a wide area network (WAN), a metropolitan area network (MAN), a satellite network, the Internet, a fiber optic network, a coaxial cable network, an infrared (IR) network, a radio frequency (RF) network, and a combination thereof. Various entities in the system environment 100 may connect to the communication network 110 in accordance with various wired and wireless communication protocols, such as Transmission Control Protocol and Internet Protocol (TCP/IP), User Datagram Protocol (UDP), Long Term Evolution (LTE) communication protocols, or any combination thereof.

FIG. 2A is a block diagram illustrating an application server 106, in which aspects of the technology may be employed. The application server 106 includes circuitry such as a parallel processor 202, a memory 204, a transceiver 206, and an input/output (I/O) port 208 that communicate with each other by way of a communication bus 210.

The parallel processor 202 may include suitable logic, circuitry, interfaces, and/or code, executable by the circuitry, that may be configured to perform one or more operations associated with the simulation of the satellite system. Examples of the parallel processor 202 may include, but are not limited to, an application-specific integrated circuit (ASIC) processor, a reduced instruction set computing (RISC) processor, a complex instruction set computing (CISC) processor, and a field-programmable gate array (FPGA). It will be apparent to a person of ordinary skill in the art that the parallel processor 202 may be compatible with multiple operating systems. In one embodiment, the parallel processor 202 may act as a simulation processing engine to simulate the orbit propagation, the link budget, the light pollution, the power analysis, the heat transfer, and the controlling of the orientation of the satellite system utilizing the system environment 100.

In an embodiment, the parallel processor 202 may be configured to process, control, and manage various functionalities and operations such as the user authentication, the reception of the set of parameters, the simulation, and the visualization, and the like. For example, the parallel processor 202 may receive the user credentials that includes the username and the password of the user 104 to authenticate the user 104 from the computing device 102 via the communication network 110. Upon successful authentication of the user 104, the parallel processor 202 may receive the set of orbital parameters from the computing device 102. Further, the parallel processor 202 may simulate the orbit propagation of the satellite system based on the set of orbital parameters to determine the set of orientation parameters of the satellite system. The set of orientation parameters may include a velocity and a position of the at least one satellite of the satellite system. The parallel processor 202 may store the velocity and the position of the at least one satellite of the satellite system in the memory 204. Further, the parallel processor 202 may dynamically render the user interface to display a visualization representing the orbit propagation of the at least one satellite of the satellite system.

Further, the parallel processor 202 may receive the selection input from the computing device 102 via the communication network 110 whether to simulate one of the link budget, the light pollution, the power analysis, the heat transfer, and the controlling of the orientation of the satellite system according to the selection by the user 104. When the selection input indicates simulation of link budget, the parallel processor 202 may receive the set of link budget parameters from the computing device 102. The set of link budget parameters may include the set of orientation parameters, a set of antenna parameters, a set of user equipment parameters, a set of environmental parameters, and a latitude and a longitude of the user equipment. The parallel processor 202 may further import the first database from the database server 108. The parallel processor 202 may select at least one analysis process of a plurality of analysis processes to process the set of link budget parameters. Based on the set of link budget parameters and the first database the parallel processor 202 may simulate the link budget of the at least one satellite of the satellite system using the selected at least one analysis process to determine the link budget of the at least one satellite. The parallel processor 202 may store the link budget of the satellite system in the memory 204. Further, the parallel processor 202 may dynamically render the user interface to display a visualization representing the link budget in coverage area of the of the satellite system.

When the selection input indicates simulation of the light pollution, the parallel processor 202 may receive the set of light pollution parameters from the computing device 102. The set of light pollution parameters may include the set of orientation parameters, a set of solar panel parameters, and a position of the Earth with respect to the Sun. The parallel processor 202 may import the second database from the database server 108. Further, the parallel processor 202 may determine a surface roughness parameter using a Gaussian distribution model. Based on the set of light pollution parameters, the second database, and the surface roughness parameter, the parallel processor 202 may simulate the light pollution by the satellite system to determine the light pollution at plurality of point of interests. The parallel processor 202 may store the light pollution at the plurality of point of interests in the memory 204. Further, the parallel processor 202 may dynamically render the user interface to display a visualization representing the light pollution by the satellite system at the plurality of point of interests.

When the selection input indicates simulation of the power analysis, the parallel processor 202 may receive the set of power analysis parameters from the computing device 102 via the communication network 110. The set of power analysis parameters may include the set of orientation parameters, the set of solar panel parameters, a set of peak values, a position of the Earth with respect to the Sun, and power consumption data of a set of components of the satellite system in each mode of operation of the satellite system. The parallel processor 202 may determine an amount of power generated and an amount of power consumed by the satellite system based on the set of power analysis parameters. Based on the amount of power generated and the amount of power consumed, the parallel processor may simulate the power analysis of the satellite system to determine an amount of power stored by the satellite system. The parallel processor 202 may store the data that includes the amount of power generated, the amount of power consumed, and the amount of power stored by the satellite system in the memory 204. Further, the parallel processor 202 may dynamically render the user interface to display a visualization representing the amount of power generated, the amount of power consumed, and the amount of power stored by the satellite system.

When the selection input indicates simulation of the heat transfer, the parallel processor 202 may receive the set of heat transfer parameters from the computing device 102 via the communication network 110. The heat transfer parameters may include the set of orientation parameters. The parallel processor 202 may determine an incoming heat energy from the Sun based on the position of the satellite system. Based on the incoming heat energy from the Sun, the parallel processor 202 may simulate the heat transfer of the satellite system to determine temperature of the satellite system. The parallel processor may store the temperature of the satellite system in the memory 204. Further, the parallel processor 202 may dynamically render the user interface to display a visualization representing the temperature of the satellite system.

When the selection input indicates simulation of the controlling of orientation of the satellite system, the parallel processor 202 may receive the set of orientation parameters, sensor data, and Global Navigation Satellite System (GNSS) data. Based on the set of orientation parameters, the sensor data, and the GNSS data, the parallel processor 202 may simulate the controlling of the satellite system to stabilize the satellite system using a machine learning model, such as a reinforcement learning model.

The memory 204 may include suitable logic, circuitry, interfaces, and/or code, executable by the circuitry, that may be configured to store one or more instructions that are executed by the parallel processor 202, the transceiver 206, and the I/O port 208 to perform their operations. The memory 204 includes buffer 205, which may be configured to receive and store the velocity and the position of the at least one satellite of the satellite system received from the parallel processor 202 after simulating the orbit propagation of the satellite system. When the parallel processor 202 simulates one of the link budget, the light pollution, the power analysis, the heat transfer, and the control of the satellite system, the buffer 205 may be configured to transmit the velocity and the position of the at least one satellite of the satellite system to the parallel processor 202.

The buffer 205 may be configured to receive store the link budget in the coverage area of the satellite system received from the parallel processor 202 after simulating link budget of the satellite system. The buffer 205 may be configured to receive and store the light pollution at the plurality of point of interests received from the parallel processor 202 after simulating the light pollution by the satellite system. Further, the buffer 205 may be configured to receive and store the data that includes the amount of power generated, the amount of power consumed, and the amount of power stored by the satellite system received from the parallel processor 202 after simulating the power analysis of the satellite system.

The buffer 205 may be further configured to receive and store the temperature of the satellite system received from the parallel processor 202 after simulating the heat transfer of the satellite system. Additionally, the buffer 205 may be configured to receive and store set of action and set of rewards utilized for controlling of the satellite system received from the parallel processor 202 after simulating the control of the satellite system. Examples of the buffer 205 may include, but are not limited to, a random-access memory (RAM), a read-only memory (ROM), a programmable ROM (PROM), an erasable PROM (EPROM), a flash memory.

The transceiver 206 may include suitable logic, circuitry, interfaces, and/or code, executable by the circuitry, that may be configured to transmit (or receive) data to (or from) various servers or devices, such as the computing device 102, or the database server 108. Examples of the transceiver 206 may include, but are not limited to, an antenna, a radio frequency transceiver, a wireless transceiver, and a Bluetooth transceiver. The transceiver 206 may be configured to communicate with the computing device 102 or the database server 108, via the communication network 110, using various wired and wireless communication protocols, such as TCP/IP, UDP, LTE communication protocols, or any combination thereof.

The I/O port 208 may include suitable logic, circuitry, interfaces, and/or code, executable by the circuitry, that may be configured to perform the one or more operations related to input or output features facilitated to the one or more users such as the user 104. The I/O port 208 may include various input and output devices that are configured to communicate with the parallel processor 202, the memory 204, and the transceiver 206. Examples of the input devices may include a keyboard, a mouse, a joystick, a touchscreen, a microphone, and the like. Examples of the output devices may include a display, a speaker, a headphone, and the like.

FIG. 2B is a block diagram illustrating the parallel processor 202, in which aspects of the technology may be employed. The parallel processor 202 includes an orbit propagation subsystem 212, a link budget subsystem 214, a light pollution subsystem 216, a power analysis subsystem 218, a guidance, navigation and control (GNC) subsystem 220, a heat transfer subsystem 222, a visualization subsystem 224, and a data export subsystem 226. The parallel processor 202 may be configured to simulate various functions of the at least one satellite or the constellation of satellites. It should be appreciated that the constellation of satellites may be arranged in different configurations, including low Earth orbit (LEO), medium Earth orbit (MEO), or geostationary orbit (GEO), depending on the intended application and the desired level of coverage and service.

The orbit propagation subsystem 212 may include suitable logic, circuitry, interfaces, and/or code, executable by the circuitry, that may be configured to simulate the orbit propagation of the satellite system. The orbit propagation subsystem 212 may be further configured to receive an input indicating whether to simulate orbit propagation for one of a single satellite of the constellation of satellites and a plurality of satellites of the constellation of satellites from the computing device 102 based on an interaction of the user 104 with the user interface rendered on the computing device 102. Further, the orbit propagation subsystem 212 may be configured to receive a set of orbital parameters associated with each satellite of the constellation of satellites from the computing device 102. When the input indicates to simulate the orbit propagation for the single satellite, the orbit propagation subsystem 212 may be configured to simulate the orbit propagation of the single satellite to determine a velocity and a position of the single satellite with respect to the Earth and the Sun based on the set of orbital parameters. When the input indicates to simulate the orbit propagation for the plurality of satellites, the orbit propagation subsystem 212 may be configured to simulate the orbit propagation of each of the plurality of satellites in parallel to determine a velocity and a position of each satellite of the plurality of satellites with respect to the Earth and the Sun based on the set of orbital parameters.

After the simulating of the orbit propagation of one of the single satellite and the plurality of satellites, the orbit propagation subsystem 212 may be further configured to store the velocity and the position of one of the single satellite and each of the plurality of satellites in the buffer 205. Further, the orbit propagation subsystem 212 may be configured to dynamically render the user interface to display a visualization representing the orbit propagation of one of the single satellite and the plurality of satellites. Additionally, the orbit propagation subsystem 212 may be configured to utilize the velocity and the position of one of the single satellite and each of the plurality of satellites for simulating one of link budget, light pollution, power analysis, heat transfer, and controlling of the orientation for at least one of the single satellite and the constellation of satellites based on the selection input and the respective parameters, the respective databases, and the respective information.

The link budget subsystem 214 may include suitable logic, circuitry, interfaces, and/or code, executable by the circuitry, that may be configured to determine link budget of the satellite system. The link budget subsystem 214 may be further configured to receive the set of orientation parameters and a set of antenna parameters associated with the at least one satellite. The set of orientation parameters may be received from the buffer 205. The set of antenna parameters may be received from the computing device 102 based on an interaction of the user 104 with the user interface rendered on the computing device 102.

The link budget subsystem 214 may be configured to receive a set of user equipment parameters associated with each user equipment of a plurality of user equipment within a coverage area of the at least one satellite and the set of environmental parameters from the computing device 102. The link budget subsystem 214 may be configured to receive the latitude and the longitude of the user equipment from the computing device 102. Further, the link budget subsystem 214 may be configured to import the first database from the database server 108. Furthermore, the link budget subsystem 214 may be further configured to process the set of orientation parameters, the set of antenna parameters, the set of user equipment parameters, the set of environmental parameters, the latitude and the longitude of the user equipment, and the first database by selecting at least one analysis process of a plurality of analysis processes.

Based on the set of orientation parameters, the set of antenna parameters, the set of user equipment parameters, the set of environmental parameters, the latitude and the longitude of the user equipment, and the first database, the link budget subsystem 214 may be configured to simulate a plurality of link budgets of the at least one satellite for each of the plurality of user equipment in parallel using the selected at least one analysis process to determine the link budgets of the at least one satellite for each of the plurality of user equipment. The link budget subsystem 214 may be configured to store the link budgets in the buffer 205 after the simulating the link budgets using the selected at least one analysis process. Further, the link budget subsystem 214 may be configured to dynamically render the user interface to display a visualization representing the link budgets in the coverage area of the at least one satellite.

The light pollution subsystem 216 may include suitable logic, circuitry, interfaces, and/or code, executable by the circuitry, that may be configured to simulate light pollution by the satellite system. The light pollution subsystem 216 may be further configured to receive the set of orientation parameters and the set of solar panel parameters associated with the at least one satellite, and the position of the Earth with respect to the Sun. The set of orientation parameters may be received from the buffer 205. The set of solar panel parameters and the position of the Earth with respect to the Sun may be received from the computing device 102 based on an interaction of the user 104 with the user interface rendered on the computing device 102.

The light pollution subsystem 216 may be configured to import the second database from the database server 108. The light pollution subsystem 216 may be further configured to determine the surface roughness parameter of the at least one satellite using the Gaussian distribution model. Based on at least one of the set of orientation parameters, the set of solar panel parameters, the position of the Earth with respect to the Sun, the surface roughness parameter, and the second database, the light pollution subsystem 216 may be configured to simulate the light pollution by the at least one satellite to determine the light pollution at the plurality of point of interests. The light pollution subsystem 216 may be configured to store the light pollution at the plurality of point of interests in the buffer 205 after simulation.

Further, the light pollution subsystem 216 may be configured to dynamically render the user interface to display a visualization representing the light pollution by the at least one satellite at the plurality of point of interests. Similarly, the light pollution subsystem 216 may be configured to simulate the light pollution by each satellite of the constellation of satellites to determine the light pollution at the plurality of point of interests in parallel based on at least one of the set of orientation parameters, the set of solar panel parameters, the position of the Earth with respect to the Sun, the surface roughness parameter, and the second database.

The power analysis subsystem 218 may include suitable logic, circuitry, interfaces, and/or code, executable by the circuitry, that may be configured to simulate power analysis of a satellite system. The power analysis subsystem 218 may be configured to receive at least one of the set of orientation parameters, the set of solar panel parameters, and a set of peak values associated with the at least one satellite, and the position of the Earth with respect to the Sun. The set of orientation parameters may be received from the buffer 205. The set of solar panel parameters, the set of peak values, and the position of the Earth with respect to the Sun may be received from the computing device 102 based on an interaction by the user 104 with the user interface rendered on the computing device 102.

Based on the set of solar panel parameters and the set of peak values associated with the at least one satellite, and the position of the Earth with respect to the Sun, the power analysis subsystem 218 may be configured to determine an amount of power generated by the at least one satellite. The power analysis subsystem 218 may be configured to receive power consumption data of a set of components of the at least one satellite in each mode of a plurality of modes of operation of the at least one satellite from the computing device 102 based on an interaction by the user 104 with the user interface rendered on the computing device 102. Based on the power consumption data of the set of components in each mode, the power analysis subsystem 218 may be configured to determine an amount of power consumed by the at least one satellite.

The power analysis subsystem 218 may be configured to simulate the power analysis of the at least one satellite, based on the amount of power generated and the amount of power consumed, to determine an amount of power stored by the at least one satellite. The power analysis subsystem 218 may be further configured to repeat receiving, determining, and simulating operations to iteratively determine the amount of power generated, the amount of power consumed, and the amount of power stored as the at least one satellite traverses through a respective orbit of the at least one satellite. Furthermore, the power analysis subsystem 218 may be configured to iteratively store data in the buffer 205 after performing the power analysis of the at least one satellite. The data includes the amount of power generated, the amount of power consumed, and the amount of power stored by the at least one satellite.

Additionally, the power analysis subsystem 218 may be configured to dynamically render the user interface to display a visualization representing the amount of power generated, the amount of power consumed, and the amount of power stored by the at least one satellite as the at least one satellite traverses through the respective orbit of the at least one satellite. Similarly, the power analysis subsystem 218, may be configured to simulate, the power analysis of each satellite of the constellation of satellites in parallel, based on the amount of power generated and the amount of power consumed, to determine an amount of power stored by each satellite of the constellation of satellites.

The GNC subsystem 220 may include suitable logic, circuitry, interfaces, and/or code, executable by the circuitry, that may be configured to control orientation of the satellite system to stabilize the satellite system. The GNC subsystem 220 may be configured to receive the set of orientation parameters from the buffer 205. Based on the set of orientation parameters, the GNC subsystem 220 may be configured to implement a reinforcement learning model to control the orientation of the satellite system to stabilize the satellite system. In one embodiment, the reinforcement learning model is based on an actor-critic model such as an actor-critic deep deterministic policy gradient model.

Alternatively, the reinforcement learning model may be based on any of Proximal Policy Optimization (PPO), Twin Delayed DDPG (TD3), Trust Region Policy Optimization (TRPO), Soft Actor-Critic (SAC), Advantage Actor-Critic (A2C), Deep Q-Network (DQN), Asynchronous Advantage Actor-Critic (A3C), Trust Region Policy Optimization with Proximal Policy Optimization (TRPO-PPO), Deterministic Policy Gradient (DPG), Continuous Actor-Critic Learning Automaton (CACLA), Generalized Advantage Estimation (GAE), Normalized Advantage Functions (NAF), Deep Deterministic Policy Gradients from Demonstrations (DDPGfD), Policy Gradient with Parameter-Based Exploration (PGPE), Natural Actor-Critic (NAC), Maximum a Posteriori Policy Optimization (MPO), Stochastic Value Gradient (SVG), Deep Episodic Value Iteration (DEVI), Distributed Distributional Deterministic Policy Gradients (D4PG), REINFORCE with Baseline models, etc.

To implement the reinforcement learning model, the GNC subsystem 220 may be configured to predict, based on each of the set of orientation parameters, a set of actions to be implemented by the satellite system to control the orientation of the satellite system, implement the set of actions, and predict an outcome of the implementing of the set of actions to generate a set of rewards. The orientation of the satellite system is controllable, based on the set of actions and the set of rewards, to stabilize the satellite system. Additionally, the GNC subsystem 220 may be configured to dynamically render the user interface to display the visualization representing the controlling and stabilization of the satellite system.

The heat transfer subsystem 222 may include suitable logic, circuitry, interfaces, and/or code, executable by the circuitry, that may be configured to simulate heat transfer for the satellite system. The heat transfer subsystem 222 may be configured to receive the set of orientation parameters from the buffer 205. Based on the set of orientation parameters, the heat transfer subsystem 222 may be configured to determine an incoming heat energy from the Sun based on the position of the at least one satellite. The heat transfer subsystem 222 may be configured to simulate heat transfer of the at least one satellite, based on the incoming heat energy, to determine temperature of the at least one satellite. Further, when the at least one satellite enter into eclipse mode, the heat transfer subsystem 222 may be configured to determine steady state temperature of the at least one satellite.

Furthermore, the heat transfer subsystem 222 may be configured to store the temperature and the steady state temperature of the at least one satellite in the buffer 205. Additionally, the heat transfer subsystem 222 may be configured to dynamically render the user interface to display a visualization representing the temperature and the steady state temperature of the at least one satellite. Similarly, the heat transfer subsystem 222 may be configured to simulate the heat transfer of each satellite of the constellation of satellites in parallel, based on the incoming heat energy, to determine the temperature of each satellite of the constellation of satellites.

The visualization subsystem 224 may include suitable logic, circuitry, interfaces, and/or code, executable by the circuitry, that may be configured to display interactive three-dimensional (3D) maps and two-dimensional (2D) plots. In one embodiment, the visualization subsystem 224 may be implemented as two different versions, such as, a desktop version and a web-based version. In one example, the desktop version may utilize PyVista which is a library in python. The visualization subsystem 224 may be further configured to receive the output of the simulation of orbit propagation of the satellite system from the orbit propagation subsystem 212.

Further, the visualization subsystem 224 may be configured to receive at least one of the link budgets in the coverage area of the satellite system, the light pollution by the satellite system at the plurality of point of interests, the amount of power generated, the amount of power consumed, and the amount of power stored by the satellite system, and the temperature of the satellite system from the link budget subsystem 214, the light pollution subsystem 216, the power analysis subsystem 218, and the heat transfer subsystem 222, respectively. Furthermore, the visualization subsystem 224 may be configured to display 3D graphs of the light pollution by the satellite system at the plurality of interests, the link budget in the coverage area of the satellite system, and the like.

The data export subsystem 226 may include suitable logic, circuitry, interfaces, and/or code, executable by the circuitry, that may be configured to export the data. The data export subsystem 226 may be further configured to receive data from at least one of the link budget subsystem 214, the light pollution subsystem 216, the power analysis subsystem 218, the GNC subsystem 220, the heat transfer subsystem 222, and the visualization subsystem 224. Further, the data export subsystem 226 may be configured to export the data in a file. Examples of the file include, but are not limited to, a motion picture expert group (MPG) file, a MATLAB file, a comma separated value (CSV) and excel file, and a text file.

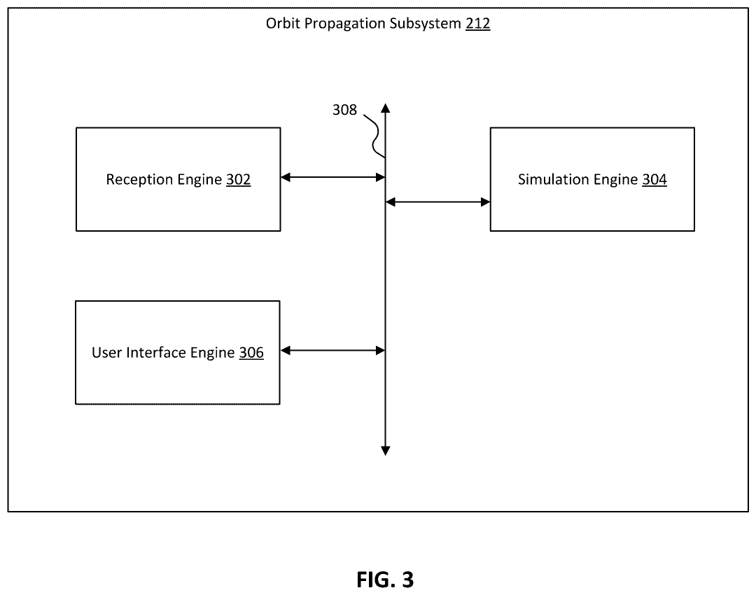

FIG. 3 is a block diagram illustrating the orbit propagation subsystem 212, in which aspects of the technology may be employed. The orbit propagation subsystem 212 includes a reception engine 302, a simulation engine 304, and a user interface engine 306 that communicate with each other by way of a communication bus 308.

The reception engine 302 may include suitable logic, circuitry, interfaces, and/or code, executable by the circuitry, that may perform one or more operations related to the reception of attributes associated to the simulation of the orbit propagation. The application server 106 may render the user interface on the computing device 102 such that the user 104 may interact with the user interface to provide the input indicating whether to simulate the orbit propagation for one of the single satellite and the plurality of satellites and the set of orbital parameters. The reception engine 302 may receive the input indicating whether to simulate the orbit propagation for one of the single satellite of the constellation of satellites and the plurality of satellites of the constellation of satellites from the computing device 102. The reception engine 302 may further receive the set of orbital parameters associated with each satellite of the constellation of satellites from the computing device 102.

The set of orbital parameters may include at least one of an inclination angle, an angle between propagating planes, an altitude of the at least one satellite, a number of propagating planes, an angle of a starting plane, a number of satellites in the constellation of satellites, a number of satellites per plane, a number of orbit period, a timestep per period, a simulation timestep, a beam angle, a day and time of launch, and a simulation period. The inclination angle may correspond to the inclination angle for the satellite in degrees. The angle between propagating planes may correspond to space between propagating planes when the satellite system includes more than one propagating plane. For example, when the satellite system includes 36 propagating planes, the angle between propagating planes may be determined as 180 divided by 36 that corresponds to five degrees. The altitude of the satellite may correspond to initial altitude of the satellite in kilometers.

The angle of the starting plane may correspond to an angle for the first propagating plane in the satellite system in degrees. For example, when the orbit propagation is simulated at Sun Synchronous Orbit (SSO) midnight noon, the angle of the starting plane may be zero degrees, and when the orbit propagation is simulated at dawn-dusk, the angle of the starting plane may be 90 degrees. The number of satellites per plane may correspond to the number of satellites per propagating plane. The number of orbit period may correspond to the number of orbits to be included in the simulation. The simulation timestep may correspond to a time interval after which the simulation may be repeated again. For example, the simulation timestep may be ten seconds, one minute, and the like. In one example, when the simulation timestep is ten seconds, the simulation may be repeated after every ten seconds. The simulation period may correspond to simulation duration. For example, the user 104 may want to perform the simulation for one day, one month, and the like. The beam angle may correspond to the beam elevation angle per satellite in degrees.

The simulation engine 304 may include suitable logic, circuitry, interfaces, and/or code, executable by the circuitry, that may perform one or more operations related to the simulation of the orbit propagation of the satellite system. The simulation engine 304 may further simulate the orbit propagation for the single satellite or for plurality of satellites based on the input received from the computing device 102. When the input indicates to simulate the orbit propagation for the single satellite, the simulation engine 304 may simulate the orbit propagation of the single satellite to determine the velocity and the position of the single satellite with respect to the Earth and the Sun based on the set of orbital parameters. The simulation engine 304 may iteratively determine the velocity and the position of the single satellite by repeating the simulating of the orbit propagation of the single satellite as the single satellite traverses through a respective orbit of that single satellite. The simulation engine may further iteratively store the velocity and the position of the single satellite in the buffer 205 after the simulating of the orbit propagation of the single satellite.

When the input indicates to simulate the orbit propagation for the plurality of satellites, the simulation engine 304 may simulate the orbit propagation of each of the plurality of satellites in parallel to determine the velocity and the position of each satellite of the plurality of satellites with respect to the Earth and the Sun based on the set of orbital parameters. The simulation engine 304 may iteratively determine the velocity and the position of each satellite of the plurality of satellites by repeating the simulating of the orbit propagation for each satellite of the plurality of satellites as each satellite of the plurality of satellites traverse through a respective orbit of that satellite. The simulation engine 304 may further iteratively store the velocity and the position of each of the plurality of satellites in the buffer 205 after the simulating of the orbit propagation of each of the plurality of satellites.

In one embodiment, the velocity and the position of the single satellite or each satellite of the plurality of satellites may be iteratively determined based on the simulation timestep. For example, the simulation timestep may be ten seconds, one minute, and the like, such that the velocity and the position of the single satellite or each satellite of the plurality of satellites may be determined iteratively after every ten seconds, every one minute, and the like, respectively. In another embodiment, the velocity and the position of the single satellite or each satellite of the plurality of satellites may be iteratively determined when the user 104 modifies the set of orbital parameters during the simulation of the orbit propagation. The user 104 may modify the set of orbital parameters based on an interaction by the user 104 with the user interface rendered on the computing device 102. For example, each time when the user 104 modifies the set of orbital parameters, the velocity and the position are determined iteratively. According to an aspect of the present disclosure, the reception engine 302 may further receive multiple sets of orbital parameters for multiple constellations of satellites from the computing device 102. Based on the multiple sets of orbital parameters, the simulation engine 304 may simulate the orbit propagation of the multiple constellations of satellites.

In one embodiment, the velocity and the position of one of the single satellite and each of the plurality of satellites and the set of link budget parameters may be further utilized to simulate the link budgets for one of the single satellite and the constellation of satellites. In another embodiment, the velocity and the position of one of the single satellite and each of the plurality of satellites and the set of power analysis parameters may be further utilized to simulate the power analysis for one of the single satellite and the constellation of satellites.

In yet another embodiment, the velocity and the position of one of the single satellite and each of the plurality of satellites and the set of light pollution parameters may be utilized to simulate the light pollution for one of the single satellite and the constellation of satellites. In yet another embodiment, the velocity and the position of one of the single satellite and each of the plurality of satellites and the set of orientation parameters may be utilized to simulate controlling of the orientation of one of the single satellite and the constellation of satellites to stabilize one of the single satellite and the constellation of satellites. In yet another embodiment, the velocity and the position of one of the single satellite and each of the plurality of satellites and the set of heat transfer parameters may be utilized to simulate the heat transfer for one of the single satellite and the constellation of satellites.

The user interface engine 306 may include suitable logic, circuitry, interfaces, and/or code, executable by the circuitry, that may perform one or more operation related to displaying the visualization. The user interface engine 306 may dynamically render the user interface to display the visualization representing the orbit propagation of one of the single satellite and the plurality of satellites based on the simulating of the orbit propagation of one of the single satellite and each of the plurality of satellites.

The visualization may correspond to at least one of a two-dimensional plot, a three-dimensional model of the Earth, and a two-dimensional contour. In one embodiment, the visualization of the orbit propagation of the single satellite may correspond to motion of the single satellite or multiple satellites that traverse through a single orbital plane around the Earth. In another embodiment, the visualization of the orbit propagation of the plurality of satellites may correspond to motion of the plurality of satellites that traverse through the single orbital plane or multiple orbital planes around the Earth. The data export subsystem 226 may receive the velocity and the position of one of the single satellite and each of the plurality of satellites as orbit propagation data from the visualization subsystem 224. Further, the data export subsystem 226 may be configured to export the orbit propagation data in a file. Examples of the file include, but are not limited to, a motion picture expert group (MPG) file, a MATLAB file, a comma separated value (CSV) and excel file, and a text file.

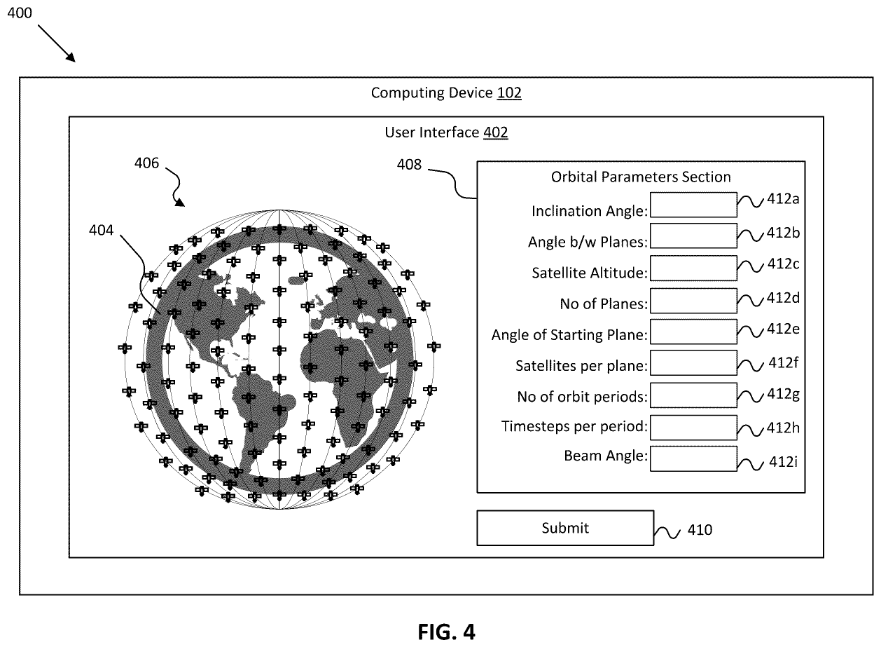

FIG. 4 is a block diagram 400 that illustrates an exemplary user interface 402 rendered on the computing device 102 in which aspects of the technology may be practiced. The user interface 402 may include representation of the Earth 404, the satellite system 406, an input section such as an orbital parameters section 408, and one interactive interface element such as an interactive interface element 410.

In an embodiment, the application server 106 may be configured to render the user interface such as the user interface 402 on the computing device 102. In one example, the representation of the Earth 404 may correspond to 3D representation of the Earth or 2D plot of the Earth. The satellite system 406 may include the at least one satellite or may correspond to the constellation of satellites. The orbital parameters section 408 includes first through ninth input fields 412a-412i. The first input field 412a may correspond to the inclination angle. The second input field 412b may correspond to the angle between the propagating planes. The third input field 412c may correspond to the satellite altitude. The fourth input field 412d may correspond to the number of propagating planes. The fifth input field 412e may correspond to the angle of the starting plane. The sixth input field 412f may correspond to the satellites per plane. The seventh input field 412g may correspond to the number of orbit period. The eight input field 412h may correspond to the timesteps per period. The ninth input field 412i may correspond to the beam angle.

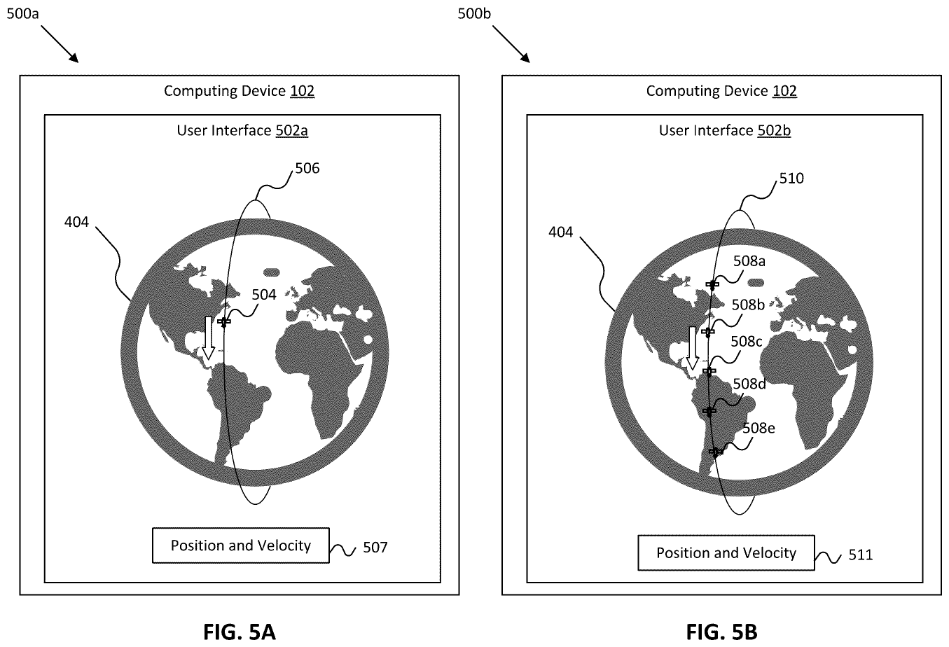

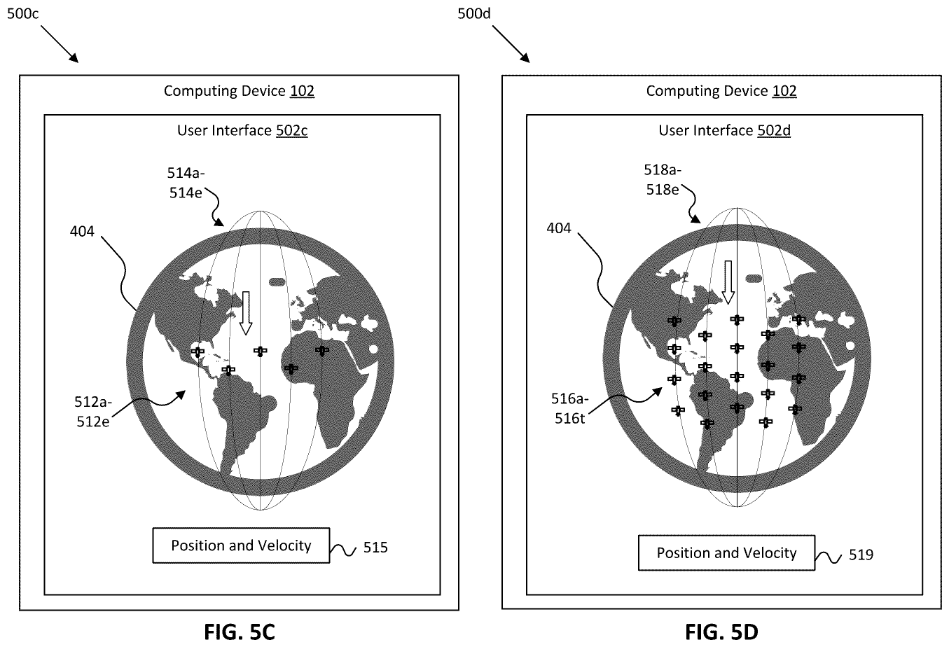

The user 104 may input the set of orbital parameters in the first through ninth input fields 412a-412i based on the interaction with the user interface 402 rendered on the computing device 102. The interactive interface element 410 may correspond to a submit button that is selectable by the user 104 to trigger or initiate the simulation of the orbit propagation of the satellite system. When the user 104 selects the submit button, the computing device 102 may transmit the set of orbital parameters to the application server 106 and the application server 106 may trigger the simulation of the orbit propagation to render one or more of the user interfaces (shown later in FIGS. 5A-5D).

FIG. 5A is a diagram 500a that represents an exemplary user interface 502a rendered on the computing device 102 in which aspects of the technology may be practiced. The user interface 502a presents the simulation of orbit propagation of a single satellite 504 of the satellite system 406 to iteratively determine a velocity and a position of the single satellite 504 with respect to the Earth and the Sun while the single satellite 504 traverses through an orbital plane 506 and the Earth 404. The user interface 502a may further include an output field 507 that displays the position and the velocity of the single satellite 504 determined based on the simulation.

FIG. 5B is a diagram 500b that represents an exemplary user interface 502b rendered on the computing device 102 in which aspects of the technology may be practiced. The user interface 502b presents the simulation of orbit propagation of each of a plurality of satellites 508a-508e of the satellite system 406 in parallel to iteratively determine a velocity and a position of each of the plurality of satellites 508a-508e with respect to the Earth and the Sun while the plurality of satellites 508a-508e traverse through a single orbital plane 510 and the Earth 404. In an embodiment, the plurality of satellites 508a-508e may include five satellites that traverse through the single orbital plane 510. It may be understood by a person skilled in the art that the plurality of satellites 508a-508e may not be limited to five and may include any suitable number of satellites, without deviating from the scope of the present disclosure. The user interface 502b may further include an output field 511 that displays the position and the velocity of each of the plurality of satellites 508a-508e determined based on the simulation.

FIG. 5C is a diagram 500c that represents an exemplary user interface 502c rendered on the computing device 102 in which aspects of the technology may be practiced. The user interface 502c presents the simulation of orbit propagation of each of a plurality of satellites 512a-512e of the satellite system 406 in parallel to iteratively determine a velocity and a position of each of the plurality of satellites 512a-512e with respect to the Earth and the Sun while the plurality of satellites 512a-512e traverse through a plurality of orbital planes 514a-514e and the Earth 404. In an embodiment, the plurality of satellites 512a-512e may include five satellites and the plurality of orbital planes 514a-514e may include five planes where there may be one satellite per orbital plane. It may be understood by the person skilled in the art that the plurality of satellites 512a-512e may include any suitable number of satellites and the plurality of orbital planes 514a-514e may include any suitable number of orbital planes, without deviating from the scope of the present disclosure. The user interface 502c may further include an output field 515 that displays the position and the velocity of each of the plurality of satellites 512a-512e determined based on the simulation.

FIG. 5D is a diagram 500d that represents an exemplary user interface 502d rendered on the computing device 102 in which aspects of the technology may be practiced. The user interface 502d presents the simulation of the orbit propagation of each of a plurality of satellites 516a-516t of the satellite system 406 in parallel to iteratively determine a velocity and a position of each of the plurality of satellites 516a-516t with respect to the Earth and the Sun while the plurality of satellites 516a-516t traverse through the plurality of orbital planes 518a-518e and the Earth 404. In an embodiment, the plurality of satellites 516a-516t may include twenty satellites and the plurality of orbital planes 518a-518e may include five planes where there may be four satellites per orbital plane. It may be understood by the person skilled in the art that the plurality of satellites 516a-516t may include any suitable number of satellites, without deviating from the scope of the present disclosure. It may be understood by the person skilled in the art that the plurality of orbital planes may include any suitable number of satellites, without deviating from the scope of the present disclosure. The user interface 502a may further include an output field 519 that displays the position and the velocity of each of the plurality of satellites 516a-516t determined based on the simulation.

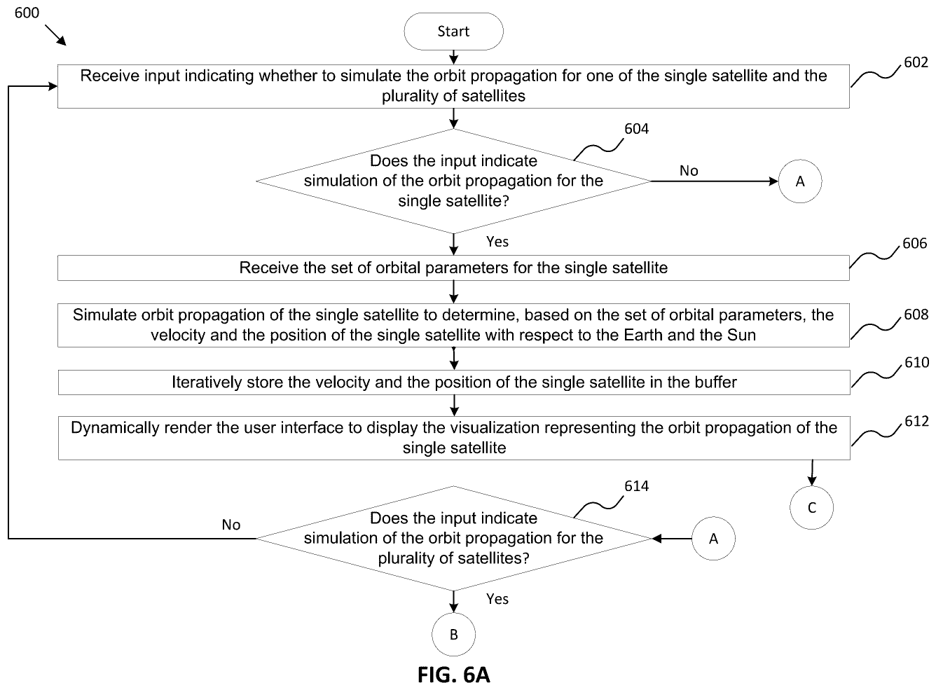

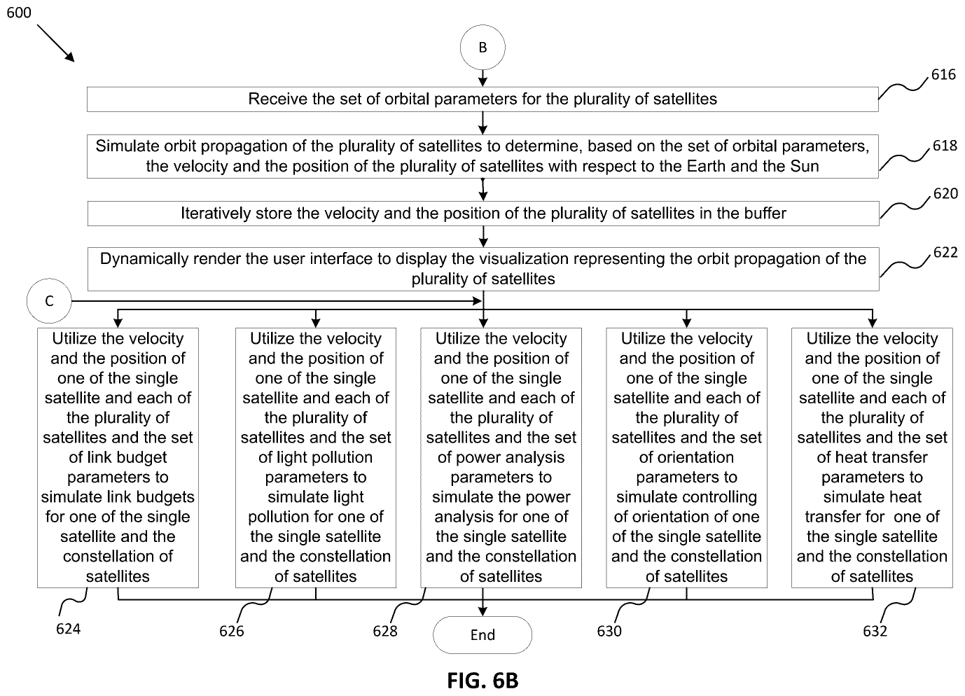

FIGS. 6A and 6B, collectively, illustrate a flow chart 600 of a method for simulating the orbit propagation of the satellite system in which aspects of the technology may be practiced.

At 602, the parallel processor 202 may receive the input indicating whether to simulate the orbit propagation for one of the single satellite of the constellation of satellites and the plurality of satellites of the constellation of satellites. At 604, the parallel processor 202 may determine whether the input indicates the simulation of the orbit propagation for the single satellite. If at 604, the parallel processor 202 determines that the input indicates the simulation of the orbit propagation for the single satellite, 606 is executed.

At 606, the parallel processor 202 may receive the set of orbital parameters for the single satellite. The set of orbital parameters may include the inclination angle, the angle between propagating planes, the altitude of the satellite, the number of propagating planes, the angle of the starting plane, the number of satellites in the constellation of satellites, the number of satellites per plane, the number of orbit period, the timesteps per period, the simulation timestep, the beam angle, the day and time of launch, and the simulation period. In an embodiment, the parallel processor 202 may receive the set of orbital parameters from the computing device 102 based on an interaction by the user 104 with the user interface 402 rendered on the computing device 102.

At 608, the parallel processor 202 may simulate the orbit propagation of the single satellite to determine the velocity and the position of the single satellite with respect to the Earth and the Sun based on the set of orbital parameters. The velocity and the position of the single satellite may be iteratively determined by repeating the simulating of the orbit propagation of the single satellite as the single satellite traverses through the respective orbit of that single satellite. In one embodiment, the velocity and the position are iteratively determined based on the simulation timestep. In another embodiment, the velocity and the position are iteratively determined when the user 104 modifies the set of orbital parameters during the simulation of the orbit propagation.

At 610, the parallel processor 202 may iteratively store the velocity and the position of the single satellite in the buffer 205 after simulating the orbit propagation of the single satellite. In one embodiment, the velocity and the position of the single satellite stored in the buffer 205 may act as demonstration data for training machine learning models such as a reinforcement learning model to implement orbit propagation of a satellite during real-time movement of the satellite along the respective orbit. Further, based on the demonstration data and the implementation of the machine learning models, control signals may be generated to control the orientation and movement of the satellite.

At 612, the parallel processor 202 may dynamically render the user interface to display the visualization representing the orbit propagation of the single satellite based on the simulating of the orbit propagation of the single satellite. The visualization may correspond to the two-dimensional plot, the three-dimensional model of the Earth, and the two-dimensional contour. If at 604, the parallel processor 202 determines that the input does not indicate simulation of the orbit propagation for the single satellite, 614 is executed.

At 614, the parallel processor 202 may determine whether the input indicates simulation of the orbit propagation for the plurality of satellites. If at 614, the parallel processor determines that the input indicates simulation of the orbit propagation for the plurality of satellites, 616 is executed. If at 614, the parallel processor 202 determines that the input does not indicates simulation of the orbit propagation for the plurality of satellites, 602 is executed.

At 616, the parallel processor 202 may receive the set of orbital parameters for the plurality of satellites. At 618, the parallel processor 202 may simulate the orbit propagation of the plurality of satellites in parallel to determine the velocity and the position of the plurality of satellites with respect to the Earth and the Sun based on the set of orbital parameters. The velocity and the position of each satellite of the plurality of satellites may be iteratively determined by repeating the simulating of the orbit propagation for each satellite of the plurality of satellites as the plurality of satellites traverse through the respective orbit of that satellite. In one embodiment, the velocity and the position are iteratively determined based on the simulation timestep. In another embodiment, the velocity and the position are iteratively determined when the user 104 modifies the set of orbital parameters during the simulation of the orbit propagation.

At 620, the parallel processor 202 may iteratively store the velocity and the position of each of the plurality of satellites in the buffer 205 after simulating the orbit propagation of the plurality of satellites.

At 622, the parallel processor 202 may dynamically render the user interface to display the visualization representing the orbit propagation of the plurality of satellites based on the simulating of the orbit propagation of the plurality of satellites. The visualization may correspond to at least one of the two-dimensional plot, the three-dimensional model of the Earth, and the two-dimensional contour. After 612 or 622, 624-632 are executed.

At 624, the parallel processor 202 may utilize the velocity and the position of one of the single satellite and each of the plurality of satellites and the set of link budget parameters to simulate the link budgets for one of the single satellite and the constellation of satellites. The link budget corresponds to a signal coverage received by a user equipment from the single satellite or the plurality of satellites over a communication channel between a transmitter of the at least one satellite and a receiver of the user equipment.

At 626, the parallel processor 202 may utilize the velocity and the position of one of the single satellite and each of the plurality of satellites and the set of light pollution parameters to simulate the light pollution for one of the single satellite and the constellation of satellites. The light pollution may correspond to the light reflected at the plurality of point of interests on the Earth by one of the single satellite and the constellation of satellites.

At 628, the parallel processor 202 may utilize the velocity and the position of one of the single satellite and each of the plurality of satellites and the set of power analysis parameters to simulate the power analysis for one of the single satellite and the constellation of satellites. The power analysis may correspond to the determination of the amount of power generated, the amount of power consumed, and the amount of power stored by one of the single satellite and the constellation of satellites.

At 630, the parallel processor 202 may utilize the velocity and the position of one of the single satellite and each of the plurality of satellites and the set of orientation parameters to simulate controlling of the orientation of one of the single satellite and the constellation of satellites to stabilize one of the single satellite and the constellation of satellites.

At 632, the parallel processor 202 may utilize the velocity and the position of one of the single satellite and each of the plurality of satellites and the set of heat transfer parameters to simulate the heat transfer for one of the single satellite and the constellation of satellites. The heat transfer may correspond to the determination of the temperature and the steady state temperature of one of the single satellite and the constellation of satellites.

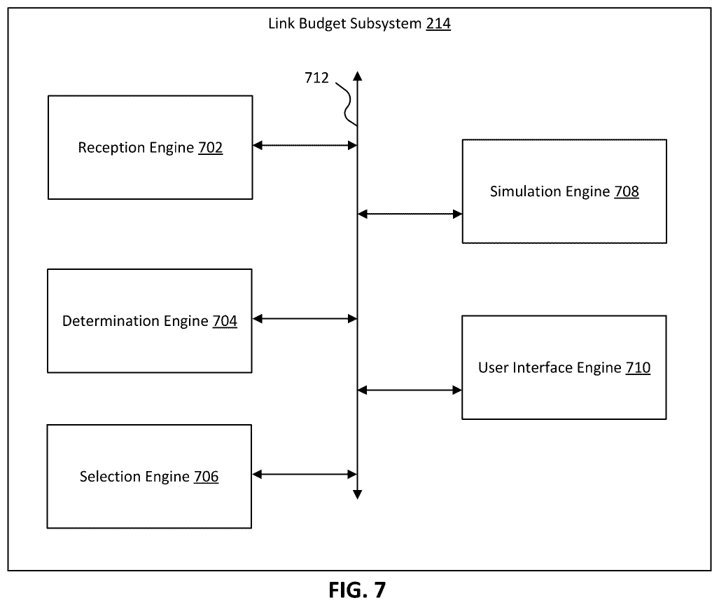

FIG. 7 is a block diagram 700 illustrating the link budget subsystem 214, in which aspects of the technology may be employed. The link budget subsystem 214 includes a reception engine 702, a determination engine 704, a selection engine 706, a simulation engine 708, and a user interface engine 710 that communicate with each other by way of a communication bus 712.

The reception engine 702 may include suitable logic, circuitry, interfaces, and/or code, executable by the circuitry, that may perform one or more operations related to the reception of attributes associated to the simulation of the link budget. The reception engine 702 may retrieve the set of orientation parameters from the buffer 205. The application server 106 may render the user interface on the computing device 102 such that the user 104 may interact with the user interface on the computing device 102 to provide the set of antenna parameters, the set of user equipment parameters, the set of environmental parameters, and the latitude and the longitude of the user equipment.

The reception engine 702 may receive the set of antenna parameters associated with the at least one satellite from the computing device 102 based on an interaction by the user 104 with the user interface rendered on the computing device 102. An antenna may provide the connection between the at least one satellite and the user equipment. The set of antenna parameters may include at least one of an antenna power, an antenna type, an antenna arrangement, physical parameters, a frequency, a bandwidth, a bit rate, an antenna orientation angle, an antenna efficiency, an antenna diameter, a polarization angle, temperature and losses in an antenna of the at least one satellite. The antenna power may correspond to an antenna amplifier power in milli watts. The antenna type may correspond to type of antenna to be used in the simulation. The antenna type may be an S-band antenna or an X-band antenna with different antenna arrangements. The antenna arrangement may include a size of an antenna array, a size of an antenna sub array, and a spacing between two antennas of the antenna sub array. The antenna type may be selectable from the list of the antenna types on the computing device 102 by the user 104 based on an interaction by the user 104 with the user interface rendered on the computing device 102.

The frequency may correspond to the frequency of a propagating wave from the antenna in megahertz. The bandwidth may correspond to the bandwidth of a signal in megahertz. The bit rate may correspond to a signal bit rate in megabytes per second (Mbps). The antenna orientation angle may correspond to the angle of the antenna with respect to a body of the satellite (for S-band type antenna). For example, when the antenna is in the direction of a radius vector (from the center of the Earth to the satellite), the antenna orientation angle may be zero. When the antenna is normal to the angle, the antenna orientation angle may be +/−90. The antenna efficiency may correspond to a percentage of the antenna efficiency.

The antenna diameter may correspond to the antenna diameter in meters. The temperature may correspond to the temperature of the satellite in Kelvin that determines noise and corresponding loss. The losses in the antenna may include at least one of an amplifier feedback loss, a feeder loss, an implementation loss, a radome loss, and all other losses in decibels (dB). The reception engine 702 may further receive the set of user equipment parameters associated with each user equipment of the plurality of user equipment within the coverage area of the at least one satellite from the computing device 102. The set of user equipment parameters may include at least one of a location of the user equipment and surroundings information associated with the user equipment.

The surroundings information indicates a type of obstruction that obstructs a communication path between the at least one satellite and the user equipment. The type of obstruction includes at least one of geographic features of landforms that obstruct a communication path between the at least one satellite and the user equipment, water that obstructs a communication path between the at least one satellite and the user equipment, soil that obstructs the communication path between the at least one satellite and the user equipment, foliage that obstructs the communication path between the at least one satellite and the user equipment, glass that obstructs the communication path between the at least one satellite and the user equipment, metal that obstructs the communication path between the at least one satellite and the user equipment, and concrete that obstructs the communication path between the at least one satellite and the user equipment.

The surroundings information for each type of obstruction further includes at least one of electrical properties of material forming an obstruction and a size of the obstruction. The electrical properties may include a loss tangent that describes to what degree a material is a conductor or insulator. The surroundings information may be received based on a selection on by the user 104 on the user interface presented on the computing device 102. In one embodiment, the user 104 may select at least one of the water, the bushes, the soil, the glass, the metal, the concrete, and the ceil panels on the user interface such that the computing device 102 provides the surrounding information based on the selection by the user 104.

The reception engine 702 may receive the set of environmental parameters from the computing device 102. The set of environmental parameters may include rain information including a raining rate and fog information including a fog probability. The set of environmental parameters may be received based on a selection by the user 104 on the user interface presented on the computing device 102. In one embodiment, the user 104 may select one of a rain and a fog on the user interface such that the computing device 102 provides the set of environmental parameters based on the selection by the user 104. The reception engine 702 may receive the latitude and the longitude of the user equipment from the computing device 102. The reception engine 702 may import the first database from the database server 108 that includes the country borders information, the ocean borders information, and the shipping lanes information. The country borders information includes border information for every region or country (e.g., Russia, USA, Britain, France, Germany, Brazil, Mexico, etc.).

Further, in an embodiment, the reception engine 702 may receive a required margin, a maximum elevation, and a constant orientation for the satellite from the computing device 102. The required margin may correspond to a minimum link margin for the satellite system in dB. The constant orientation for the satellite may include a constant roll, a constant pitch, and a constant yaw. The link budget and an antenna gain may be determined based on the constant orientation.

Additionally, the reception engine 702 may receive a set of ground object parameters that includes an antenna identifier (ID), an antenna name, a user altitude, lands to exclude, and an input indicating whether to exclude ocean water and include shipping lanes in coverage. The antenna ID may correspond to ID of the user equipment or define the position of the user equipment. The user altitude may correspond to an altitude of the user equipment in kilometer. The lands to exclude may correspond to excluding coverage for specific regions. The lands to exclude may be selectable from the list of the lands on the computing device 102 by the user 104 based on an interaction by the user 104 with the user interface rendered on the computing device 102. The input indicating whether to exclude ocean water and include shipping lanes in coverage may be received based on a selection by the user 104 on the computing device 102. In one embodiment, the user 104 may select at least one of the exclude ocean water and the including shipping lane on the user interface such that the computing device 102 provides the exclude ocean water and the including shipping lanes based on the selection by the user 104.

The determination engine 704 may include suitable logic, circuitry, interfaces, and/or code, executable by the circuitry, that may perform one or more operations related to determination of parameters associated with link budget based on the received attributes. The determination engine 704 may determine beam shaping information, beam forming information, and beam steering information based on the size of the antenna sub array. The link budgets of the at least one satellite for each of the plurality of user equipment are determined further based on the beam shaping information, the beam forming information, and the beam steering information.

The beam shaping information may correspond to information associated with beam shaping which is the process of designing the footprint of a satellite signal on the Earth's surface. Beam shaping involves adjusting the power distribution and phase across the satellite antenna to create a desired coverage area, which may be shaped to match specific geographic regions or to avoid interference with other signals. The beam forming information may correspond to information associated with beamforming in satellites which refers to the use of multiple antenna elements to transmit or receive signals in a way that enhances the signal strength in a particular direction, achieved by controlling the phase and amplitude of the signal at each antenna element, resulting in a focused, high-gain beam that may be directed towards a specific area or target, improving communication quality and efficiency. The beam steering information may correspond to information associated with beam steering for satellites which involves dynamically changing the direction of the beam or beams generated by the satellite's antenna system. Beam steering may be done electronically, without physically moving the antenna, by altering the relative phases of the signals emitted by different antenna elements. Beam steering is important for tracking mobile users or adjusting the coverage area in response to changing demand or conditions.

The determination engine 704 may determine a region in which the user equipment is located based on the first database. In one embodiment, the determination engine 704 may determine a country in which the user equipment is located based on the country borders information and the latitude and the longitude of the user equipment. The link budgets of the at least one satellite for each of the plurality of user equipment are determined further based on the country in which the user equipment is located.

In another embodiment, based on the shipping lanes information and the latitude and the longitude of the user equipment, the determination engine 704 may determine whether the user equipment is located on a shipping lane in an ocean. The link budgets of the at least one satellite for each of the plurality of user equipment are determined further based on whether the user equipment is located on the shipping lane in the ocean. Hence, based on the first database, the determination engine 704 may determine whether the user equipment is on the shipping lane in the ocean or in the different countries.

For example, when coverage over Russia is not required, Russia may be selectable from the list of lands in the lands to exclude on the computing device 102 by the user 104 based on the interaction with the user interface rendered on the computing device 102. Further, during the simulation of the link budget when the satellite is over Russia, the determination engine 704 may turn off the satellite based on a selection by the user 104, the country borders information, and the latitude and the longitude of the user equipment and hence, the link budget becomes zero. The link budget subsystem 214 may send the signal to the power analysis subsystem 218 that there is no power within the link budget that helps to save the energy.

For example, when coverage over the ocean waters is not required, exclude ocean water may be selectable on the computing device 102 by the user 104 based on the interaction with the user interface rendered on the computing device 102. Further, during the simulation of the link budget when the satellite is over the ocean waters, the determination engine 704 may turn of the satellite based on a selection by the user 104, the ocean borders information, and the latitude and the longitude of the user equipment.

When coverage over the shipping lanes of the ocean is required, include shipping lanes may be selectable on the computing device 102 by the user 104 based on the interaction with the user interface rendered on the computing device 102. Further, during the simulation of the link budget when the satellite is over the ocean waters that includes shipping lanes, the determination engine 704 may turn on the satellite based on a selection by the user 104, the ocean borders information, the shipping lane information, and the latitude and the longitude of the user equipment.

The determination engine 704 may determine a change in the signal coverage for the user equipment based on the surroundings information. The link budgets of the at least one satellite for each of the plurality of user equipment are determined further based on the change in the signal coverage. The change in the signal coverage may be determined when the user equipment may be under water with specific depth, when the user equipment is sitting in a car behind bushes, glass, and concrete, or the like.

For example, when the user equipment may be under water with depth two feet, the water may be selectable on the computing device 102 by the user 104 in the surroundings information based on an interaction by the user 104 with the user interface on the computing device 102. Further, the determination engine 704 may determine the change in the signal coverage for the user equipment under water based on the selection by the user 104.

The determination engine 704 may determine a change in the signal coverage for the user equipment based on the raining rate and the fog probability. The raining rate and the fog probability may add fidelity or perturbations. The link budgets of the at least one satellite for each of the plurality of user equipment are determined further based on the change in the signal coverage.

The selection engine 706 may include suitable logic, circuitry, interfaces, and/or code, executable by the circuitry, that may perform one or more operations related to select the analysis process for processing the attributes associated to the simulation of the link budget. The selection engine 706 may select at least one analysis process of the plurality of analysis processes to process the set of orientation parameters, the set of antenna parameters, the set of user equipment parameters, the set of environmental parameters, the latitude and the longitude of the user equipment, and the first database. The plurality of analysis processes may include at least one of a two-dimensional analysis, a three-dimensional analysis, and a hexagonal hierarchical geospatial indexing system (H3) discretization.

The H3 discretization may refer to a specific spatial discretization scheme based on a H3 hexagon grid system. A H3 grid is a spatial indexing system that partitions the Earth's surface into hexagons of varying sizes. Hexagons may be preferred over squares because they provide a more uniform representation of the Earth's surface, especially at different latitudes. The H3 grid system may include a hierarchical structure in which hexagons may be nested within each other at different resolution levels. The H3 discretization may be configured to cover the entire surface of the Earth to provide a global spatial indexing system. Each hexagon in the H3 grid is assigned a unique address, i.e., a H3 index.

The simulation engine 708 may include suitable logic, circuitry, interfaces, and/or code, executable by the circuitry, that may perform one or more operations related to simulation of link budget of the satellite system. The simulation engine 708 may simulate the plurality of link budgets of the at least one satellite for each of the plurality of user equipment in parallel using the selected at least one analysis process to determine link budgets of the at least one satellite for each of the plurality of user equipment based on the set of orientation parameters, the set of antenna parameters, the set of user equipment parameters, the set of environmental parameters, the first database, and the latitude and the longitude of the user equipment.

The link budgets of the at least one satellite are iteratively determined as the at least one satellite traverses through a respective orbit of the at least one satellite. In one embodiment, the link budgets may be iteratively determined based on the simulation timestep. For example, the simulation timestep may be ten seconds, one minute, and the like, such that the link budgets may be determined iteratively after every ten seconds, every one minute, and the like, respectively. In another embodiment, the link budgets may be iteratively determined when the user 104 modifies at least one of the set of orientation parameters, the set of antenna parameters, the set of user equipment parameters, the set of environmental parameters, and the latitude and the longitude of the user equipment during the simulation of the link budget. The user 104 may modify at least one of the set of orientation parameters, the set of antenna parameters, the set of user equipment parameters, the set of environmental parameters, and the latitude and the longitude of the user equipment based on the interaction with the user interface rendered on the computing device 102. For example, each time when the user 104 modifies at least one of the set of orientation parameters, the set of antenna parameters, the set of user equipment parameters, the set of environmental parameters, and the latitude and the longitude of the user equipment, the link budgets are determined iteratively.

After the simulating the link budgets of the at least one satellite using the selected at least one analysis process, the simulation engine may store the link budgets in the buffer 205. According to an aspect of the present disclosure, the reception engine 702 may further receive multiple sets of orientation parameters for multiple constellations of satellites from the buffer 205 and multiple sets of antenna parameters, user equipment parameters, and environmental parameters for the multiple constellations of satellites from the computing device 102. Based on the multiple sets of orientation parameters, antenna parameters, user equipment parameters, and environmental parameters, the simulation engine 708 may simulate the link budget of the multiple constellations of satellites.

The link budget may correspond to the signal coverage received by the user equipment from the at least one satellite over the communication channel between the transmitter of the at least one satellite and the receiver of the user equipment. The link budget includes a power budget of the communication channel between the transmitter of the at least one satellite and the receiver of the user equipment to achieve sufficient received signal power at the receiver to maintain reliable communication connectivity between the transmitter and the receiver.

The user interface engine 710 may include suitable logic, circuitry, interfaces, and/or code, executable by the circuitry, that may perform one or more operation related to displaying the visualization. The user interface engine 710 may dynamically render the user interface to display the visualization representing the link budgets in the coverage area of the at least one satellite based on the simulating of the plurality of link budgets. The visualization corresponds to at least one of the two-dimensional plot, the three-dimensional model of the Earth, and the two-dimensional contour.

The user interface engine 710 may display three-dimensional graphs of the signal coverage received by the user equipment from the at least one satellite. In an embodiment, when the user 104 interacts with the user interface to indicate interest in the signal coverage over one specific location, the user interface engine 710 may display two-dimensional plot of the signal coverage. The data export subsystem 226 may receive the link budgets in the coverage area of the at least one satellite as link budget data from the visualization subsystem 224 or the link budget subsystem 214. Further, the data export subsystem 226 may be configured to export the link budget data in a file. Examples of the file include, but are not limited to, a motion picture expert group (MPG) file, a MATLAB file, a comma separated value (CSV) and excel file, and a text file.

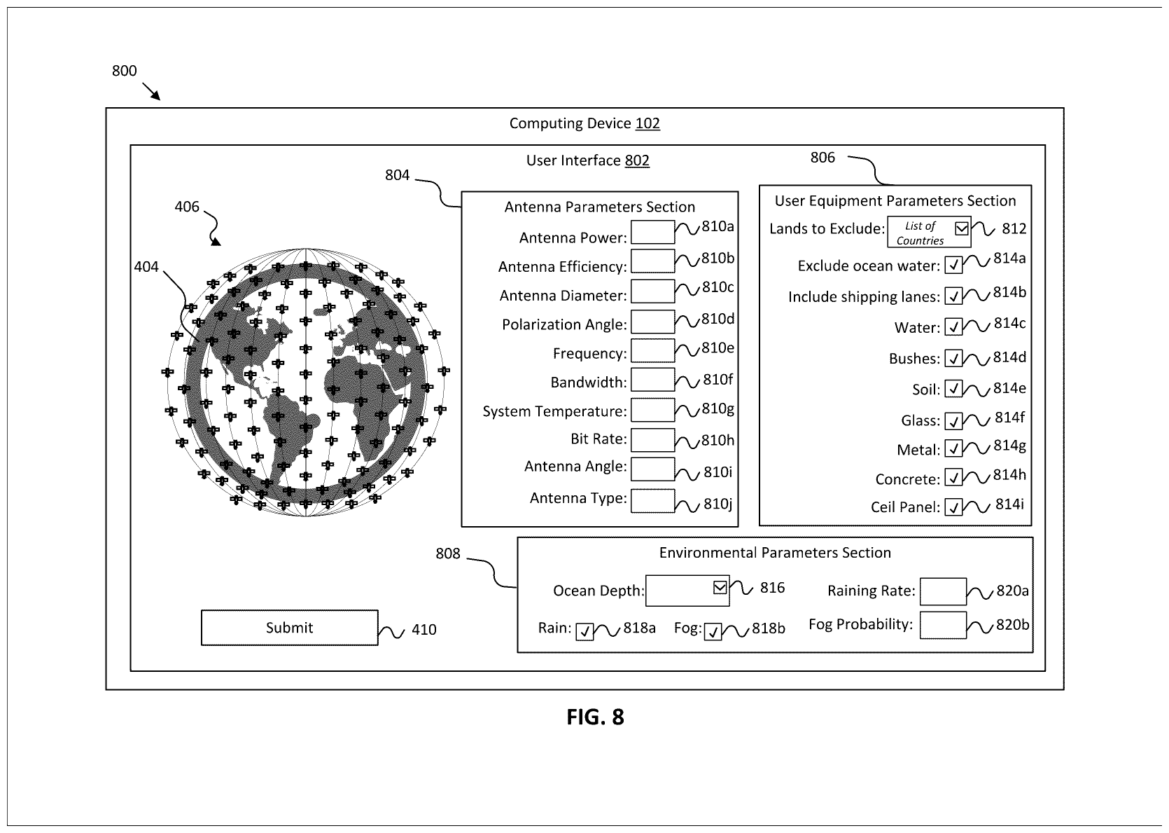

FIG. 8 is a block diagram 800 that illustrates an exemplary user interface 802 rendered on the computing device 102 in which aspects of the technology may be practiced. The user interface 802 may include representation of the Earth 404, the satellite system 406, one or more input sections such as an antenna parameters section 804, a user equipment parameters section 806, and an environmental parameters section 808, and one interactive interface element such as the interactive interface element 410.

In an embodiment, the application server 106 may be configured to render the user interface such as the user interface 802 on the computing device 102. In one embodiment, the representation of the Earth 404 may correspond to 3D representation of the Earth or 2D plot of the Earth. The satellite system 406 may include the at least one satellite or may correspond to the constellation of satellites. The antenna parameters section 804 includes first through tenth input field 810a-810j. The first input field 810a may correspond to the antenna power. The second input field 810b may correspond to the antenna efficiency. The third input field 810c may correspond to the antenna diameter. The fourth input field 810d may correspond to the polarization angle. The fifth input field 810e may correspond to the frequency. The sixth input field 810f may correspond to the bandwidth. The seventh input field 810g may correspond to the temperature. The eighth input field 810h may correspond to the bit rate. The ninth input field 810i may correspond to the antenna angle. The tenth input field 810j may correspond to the antenna type. The user 104 may input the set of antenna parameters in the first through tenth input fields 810a-810j based on the interaction with the user interface 802 rendered on the computing device 102.

The user equipment parameters section 806 includes dropdown list 812 and one or more checkboxes, such as first through ninth checkboxes 814a-814i. The dropdown list 812 may correspond to the lands to exclude and includes list of countries. The first checkbox 814a may correspond to the exclude ocean water. The second checkbox 814b may correspond to include the shipping lanes. The third checkbox 814c may correspond to the water. The fourth checkbox 814d may correspond to the bushes. The fifth checkbox 814e may correspond to the soil. The sixth checkbox 814f may correspond to the glass. The seventh checkbox 814g may correspond to the metal. The eight checkbox 814h may correspond to the concrete. The ninth checkbox 814i may correspond to the ceil panels.

The country may be selectable from the list of countries in the dropdown list 812 on the computing device 102 by the user 104 based on the interaction with the user interface 802 rendered on the computing device 102. At least one of options such as, the exclude ocean water, the include shipping lanes, the water, the bushes, the soil, glass, metal, concrete, and ceil panels may be selectable on the computing device 102 by the user 104 based on the interaction with the user interface 802 rendered on the computing device 102. Based on the selection by the user 104, the computing device 102 may transmit the set of user equipment parameters to the application server 106.

The environmental parameters section 808 includes a dropdown list 816, one or more checkboxes, such as first and second checkboxes 818a and 818b, and one or more input fields, such as first and second input fields 820a and 820b. The dropdown list 816 may correspond to the ocean depth. The first checkbox 818a may correspond to the rain. The second checkbox 818b may correspond to the fog. The first input field 820a may correspond to the raining rate. The second input field 820b may correspond to the fog probability.

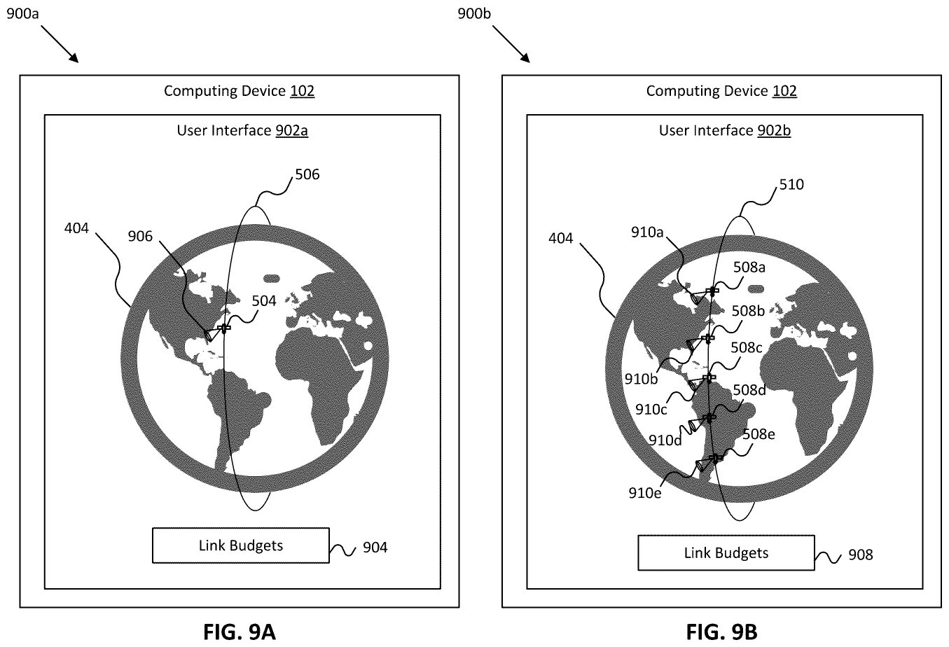

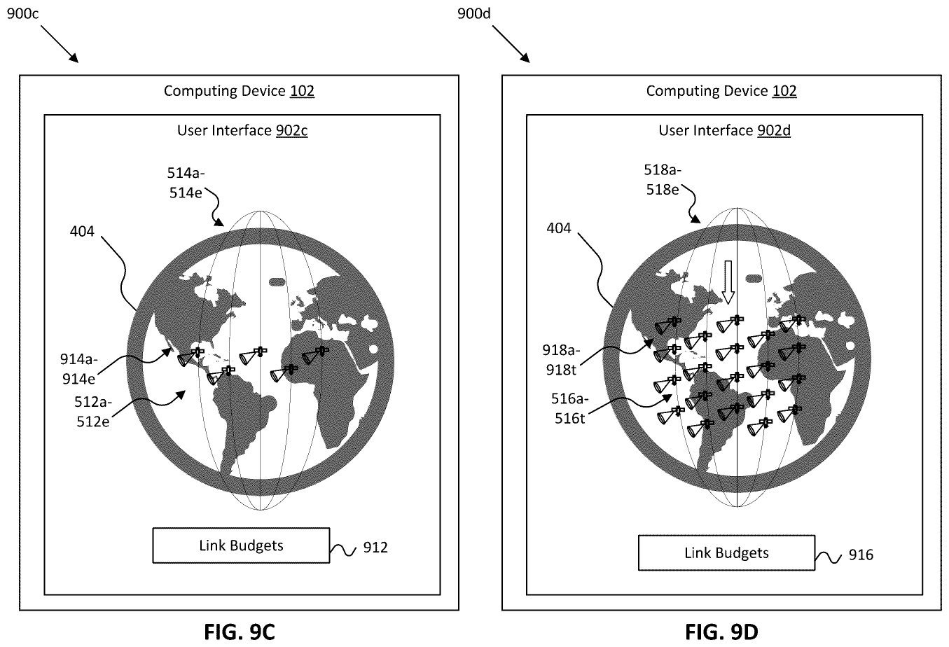

The user 104 may input the set of link budget parameters in the antenna parameters section 804, the user equipment parameters section 806, and the environmental parameters section 808 based on the interaction with the user interface 802 rendered on the computing device 102. The interactive interface element 410 may correspond to the submit button that is selectable by the user 104 to trigger or initiate the simulation of the link budget of the satellite system. When the user 104 selects the submit button, the computing device 102 may transmit the antenna parameters, the user equipment parameters, and the environmental parameters to the application server 106 and the application server 106 may trigger the simulation of the link budget and render one of the user interfaces (shown later in FIGS. 9A-9D).

FIG. 9A is a diagram 900a that represents an exemplary user interface 902a rendered on the computing device 102 in which aspects of the technology may be practiced. The user interface 902a presents the simulation of link budget of the single satellite 504 of the satellite system 406 to iteratively determine a plurality of link budgets of the single satellite 504 for each of the plurality of user equipment while the single satellite 504 traverses through an orbital plane 506 and the Earth 404. The user interface 902a may further include an output field 904 that displays the link budgets of the single satellite 504 for all the user equipment within a coverage area 906 of the single satellite 504 determined based on the simulation.

FIG. 9B is a diagram 900b that represents an exemplary user interface 902b rendered on the computing device 102 in which aspects of the technology may be practiced. The user interface 902b presents the simulation of link budget of the plurality of satellites 508a-508e of the satellite system 406 to iteratively determine a plurality of link budgets of the plurality of satellites 508a-508e in parallel for each of the plurality of user equipment while the plurality of satellites 508a-508e traverse through the single orbital plane 510 and the Earth 404. In an embodiment, the plurality of satellites 508a-508e may include five satellites that traverse through the single orbital plane 510. It may be understood by the person skilled in the art that the plurality of satellites 508a-508e may not be limited to five and may include any suitable number of satellites, without deviating from the scope of the present disclosure. The user interface 902b may further include an output field 908 that displays the link budgets of each of the plurality of satellites 508a-508e for the user equipment within coverage areas 910a-910e of the plurality of satellites 508a-508e, respectively, determined based on the simulation.

FIG. 9C is a diagram 900c that represents an exemplary user interface 902c rendered on the computing device 102 in which aspects of the technology may be practiced. The user interface 902c presents the simulation of link budget of the plurality of satellites 512a-512e of the satellite system 406 to iteratively determine a plurality of link budgets of the plurality of satellites 512a-512e in parallel for each of the plurality of user equipment while the plurality of satellites 512a-512e traverse through the plurality of orbital planes 514a-514e and the Earth 404. In an embodiment, the plurality of satellites 512a-512e may include five satellites and the plurality of orbital planes 514a-514e may include five planes where there may be one satellite per orbital plane. It may be understood by the person skilled in the art that the plurality of satellites 512a-512e may include any suitable number of satellites and the plurality of orbital planes 514a-514e may include any suitable number of orbital planes, without deviating from the scope of the present disclosure. The user interface 902c may further include an output field 912 that displays the link budgets of each of the plurality of satellites 512a-512e for the user equipment within coverage areas 914a-914e of the plurality of satellites 512a-512e, respectively, determined based on the simulation.

FIG. 9D is a diagram 900d that represents an exemplary user interface 902d rendered on the computing device 102 in which aspects of the technology may be practiced. The user interface 902d presents the simulation of link budget of the plurality of satellites 516a-516t of the satellite system 406 to iteratively determine a plurality of link budgets of the plurality of satellites 516a-516t in parallel for each of the plurality of user equipment while the plurality of satellites 516a-516t traverse through the plurality of orbital planes 518a-518e and the Earth 404. In an embodiment, the plurality of satellites 516a-516t may include twenty satellites and the plurality of orbital planes 518a-518e may include five planes where there may be four satellites per orbital plane. It may be understood by the person skilled in the art that the plurality of satellites 516a-516t may include any suitable number of satellites, without deviating from the scope of the present disclosure. It may be understood by the person skilled in the art that the plurality of orbital planes may include any suitable number of satellites, without deviating from the scope of the present disclosure. The user interface 902d may further include an output field 916 that displays the link budgets of each of the plurality of satellites 516a-516t for the user equipment within coverage areas 918a-918t of the plurality of satellites 516a-516t, respectively, determined based on the simulation.

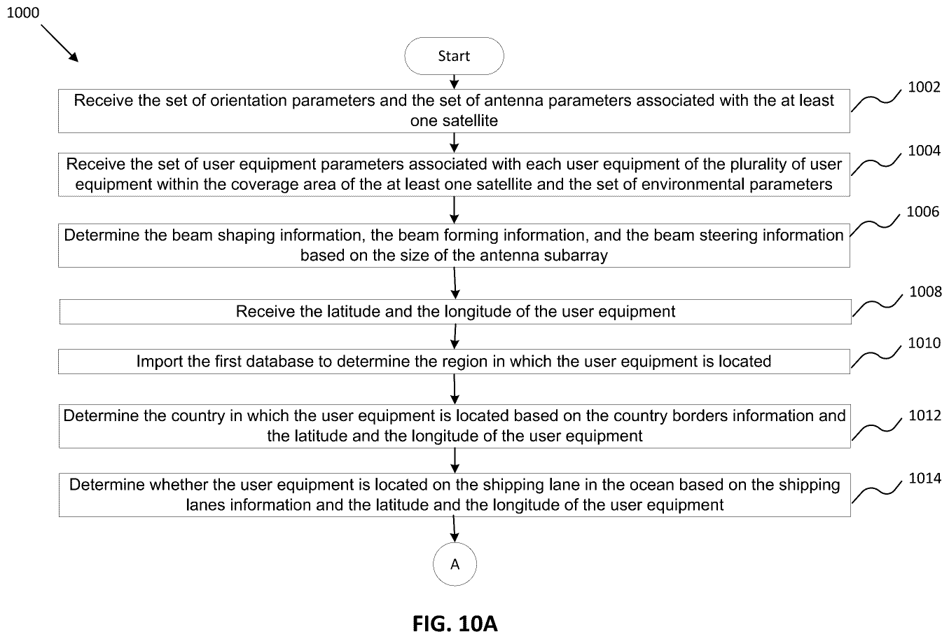

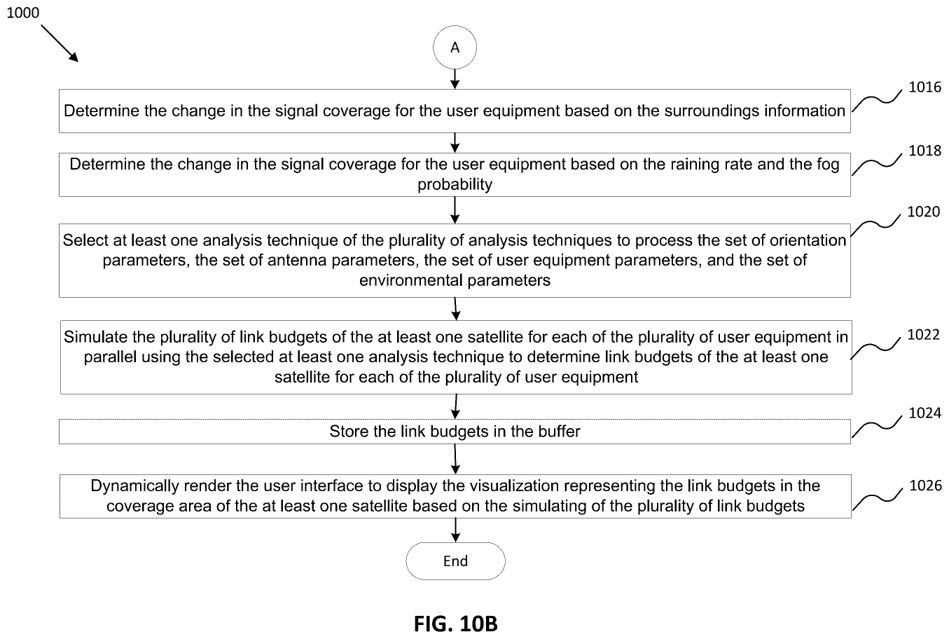

FIGS. 10A and 10B, collectively, illustrate a flow chart 1000 of a method for simulating the link budget of the satellite system according to aspects of the disclosed technology.

At 1002, the parallel processor 202 may receive the set of orientation parameters and the set of antenna parameters associated with the at least one satellite. The set of orientation parameters may include the velocity and the position of the at least one satellite. In an embodiment, the parallel processor 202 may receive the set of orientation parameters from the buffer 205. The set of antenna parameters may include at least one of the antenna power, the antenna type, the antenna arrangement, physical parameters, the frequency, the bandwidth, the bit rate, the antenna orientation angle, the antenna efficiency, the antenna diameter, the polarization angle, the temperature and losses in the antenna of the at least one satellite. In an embodiment, the parallel processor 202 may receive the set of antenna parameters from the computing device 102 based on the interaction with the user interface 802 rendered on the computing device 102.

At 1004, the parallel processor 202 may receive the set of user equipment parameters associated with each user equipment of the plurality of user equipment within the coverage area of the at least one satellite and the set of environmental parameters. The set of user equipment parameters may include at least one of the location of the user equipment and surroundings information that indicate the type of obstruction that obstructs the communication path between the at least one satellite and the user equipment. The set of environmental parameters may include at least one of the rain information and the fog information. In one embodiment, the parallel processor 202 may receive the set of user equipment parameters and the set of environmental parameters from the computing device 102 based on the interaction with the user interface 802 rendered on the computing device 102.

At 1006, the parallel processor 202 may determine the beam shaping information, the beam forming information, and the beam steering information based on the size of the antenna sub array. At 1008, the parallel processor 202 may receive the latitude and the longitude of the user equipment. In an embodiment, the parallel processor 202 may receive the latitude and the longitude of the user equipment from the computing device 102 based on the interaction with the user interface rendered on the computing device 102.

At 1010, the parallel processor 202 may import the first database to determine the region in which the user equipment is located. The first database includes the country borders information, the ocean borders information, and the shipping lanes information. In an embodiment, the parallel processor 202 may import the first database from the database server 108.

At 1012, the parallel processor 202 may determine the country in which the user equipment is located based on the country borders information and the latitude and the longitude of the user equipment. At 1014, the parallel processor 202 may determine whether the user equipment is located on the shipping lane in the ocean based on the shipping lanes information and the latitude and the longitude of the user equipment.

At 1016, the parallel processor 202 may determine the change in the signal coverage for the user equipment based on the surroundings information. At 1018, the parallel processor 202 may determine the change in the signal coverage for the user equipment based on the raining rate and the fog probability.

At 1020, the parallel processor 202 may select at least one analysis process of the plurality of analysis processes to process the set of orientation parameters, the set of antenna parameters, the set of user equipment parameters, and the set of environmental parameters. The plurality of analysis processes includes at least one of the two-dimensional analysis, the three-dimensional analysis, and the hexagonal hierarchical geospatial indexing system (H3) discretization.

At 1022, the parallel processor 202 may simulate the plurality of link budgets of the at least one satellite for each of the plurality of user equipment in parallel using the selected at least one analysis process to determine link budgets of the at least one satellite for each of the plurality of user equipment based on the set of orientation parameters, the set of antenna parameters, the set of user equipment parameters, the set of environmental parameters, the first database, and the latitude and the longitude of the user equipment. In one embodiment, the link budgets of the at least one satellite for each of the plurality of user equipment are determined further based on one of the beam shaping information, the beam forming information, and the beam steering information, the country in which the user equipment is located, whether the user equipment is located on the shipping lane in the ocean, and the change in the signal coverage.

The link budgets of the at least one satellite are iteratively determined as the at least one satellite traverses through the respective orbit of the at least one satellite. In one embodiment, the link budgets may be iteratively determined based on the simulation timestep. In another embodiment, the link budgets may be iteratively determined when the user 104 modifies at least one of the set of orientation parameters, the set of antenna parameters, the set of user equipment parameters, the set of environmental parameters, and the latitude and the longitude of the user equipment during the simulation of the link budget. The user 104 may modify at least one of the set of orientation parameters, the set of antenna parameters, the set of user equipment parameters, the set of environmental parameters, and the latitude and the longitude of the user equipment based on an interaction by the user 104 with the user interface rendered on the computing device 102.

At 1024, the parallel processor 202 may store the link budgets in the buffer 205 after the simulating using the selected at least one analysis process. At 1026, the parallel processor 202 may dynamically render the user interface to display the visualization representing the link budgets in the coverage area of the at least one satellite based on the simulating of the plurality of link budgets. The visualization may correspond to at least one of the two-dimensional plot, the three-dimensional model of the Earth, and the two-dimensional contour.

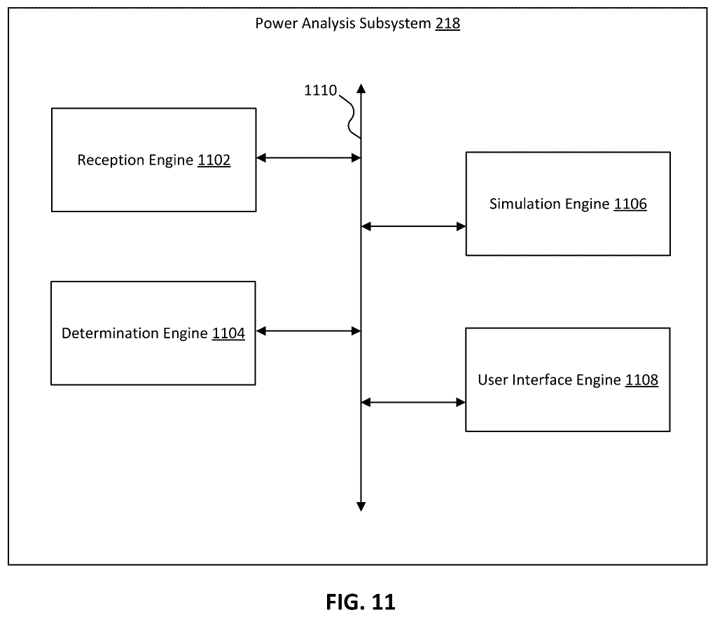

FIG. 11 is a block diagram illustrating the power analysis subsystem 218 in which aspects of the technology may be employed. The power analysis subsystem 218 includes a reception engine 1102, a determination engine 1104, a simulation engine 1106, and a user interface engine 1108 that communicate with each other by way of a communication bus 1110.

The reception engine 1102 may include suitable logic, circuitry, interfaces, and/or code, executable by the circuitry, that may perform one or more operations related to the reception of attributes associated to the simulation of the power analysis. The reception engine 1102 may receive the attributes of the at least one satellite or each satellite of the constellation of satellites. The reception engine 1102 may retrieve the set of orientation parameters associated with the at least one satellite from the buffer 205.

The reception engine 1102 may retrieve the set of orientation parameters associated with each satellite of the constellation of satellites from the buffer 205. The application server 106 may render the user interface on the computing device 102 such that the user 104 may interact with the user interface on the computing device 102 to provide the set of solar panel parameters, and the set of peak values associated with each satellite of the constellation of satellites, and the position of the Earth with respect to the Sun, and the power consumption data of the set of components of each satellite of the constellation of satellites in each mode of the plurality of modes of operation of each satellite of the constellation of satellites.

The reception engine 1102 may receive the set of solar panel parameters associated with the at least one satellite and each satellite of the constellation of satellites from the computing device 102. The set of solar panel parameters includes at least one of a number of solar panels, dimensions of the solar panels, a model of the solar panels, and an efficiency of the solar panels. The dimensions of the solar panels may specify length of a solar panel in meter and width of the solar panel in meter. The reception engine 1102 may receive the set of peak values associated with the at least one satellite and each satellite of the constellation of satellites from the computing device 102. The set of peak values includes at least one of peak power of the solar panels, a maximum battery capacity, and a battery load. The peak power of the solar panels may specify maximum power of the solar panels when the solar panels are facing the sun in a 90-degree manner, i.e., the area facing the sunlight is maximum. The battery load may specify a constant load in watts to perform the calculations for the battery cycles. The set of solar panel parameters and the set of peak values may be received based on a selection by the user 104 on the computing device 102. In one embodiment, the user 104 may select at least one of the set of solar panel parameters and the set of peak values on the user interface such that the computing device 102 provides the set of solar panel parameters and the set of peak values based on the selection by the user 104.

The reception engine 1102 may receive the power consumption data of the set of components of the at least one satellite in each mode of the plurality of modes of operation of the at least one satellite and the power consumption data of the set of components of each satellite of the constellation of satellites in each mode of the plurality of modes of operation of each satellite of the constellation of satellites from the computing device 102. The set of components includes a set of sensors of the at least one satellite and each satellite of the constellation of satellites. Examples of the set of sensors may include, but are not limited to: magnetometers, gyroscopes, accelerometers, star trackers, sun sensors, Earth sensors, Global Positioning System (GPS) receivers, Global Navigation Satellite System (GNSS) receivers, and the like. The plurality of modes includes at least one of a launch and deployment mode, a commissioning phase mode, a nominal operations mode, a safe mode, a maneuvering mode, and a recovery and end of life mode.

The determination engine 1104 may include suitable logic, circuitry, interfaces, and/or code, executable by the circuitry, that may perform one or more operations related to determination of parameters associated with power analysis based on the attributes received. The determination engine 1104 may further determine the parameters of the at least one satellite and each satellite of the constellation of satellites associated with power analysis. Further, the determination engine 1104 may determine an incoming energy from the Sun at the at least one satellite based on the set of orientation parameters and the position of the Earth with respect to the Sun.

In one embodiment, when the user 104 selects the set of solar panel parameters associated with the at least one satellite on the computing device 102 based on an interaction by the user 104 with the user interface rendered on the computing device 102, the determination engine 1104 may determine the amount of power generated by the at least one satellite based on the incoming energy from the Sun and the set of solar panel parameters. In another embodiment, when the user 104 selects the set of peak values associated with the at least one satellite on the computing device 102 based on the interaction with the user interface rendered on the computing device 102, the determination engine 1104 may determine the amount of power generated by the at least one satellite based on the incoming energy from the Sun and the set of peak values. In yet another embodiment, when the user 104 select the set of solar panel parameters and the set of peak values associated with the at least one satellite on the computing device 102 based on the interaction with the user interface rendered on the computing device 102, the determination engine may determine the amount of power generated by the at least one satellite based on the incoming energy from the Sun, the set of solar panel parameters, and the set of peak values.

The determination engine 1104 may further determine the amount of power consumed by the at least one satellite based on the power consumption data of the set of components in each mode. The power consumption data includes the amount of power consumed by each component of the set of components and the amount of power consumed by each mode of the plurality of modes.

The determination engine 1104 may determine an incoming energy from the Sun at each satellite of the constellation of satellites based on the set of orientation parameters and the position of the Earth with respect to the Sun. In one embodiment, when the user 104 selects the set of solar panel parameters associated with each satellite of the constellation of satellites satellite on the computing device 102 based on the interaction with the user interface rendered on the computing device 102, the determination engine 1104 may determine the amount of power generated by each satellite of the constellation of satellites based on the incoming energy from the Sun and the set of solar panel parameters.

In another embodiment, when the user 104 selects the set of peak values associated with each satellite of the constellation of satellites satellite on the computing device 102 based on the interaction with the user interface rendered on the computing device 102, the determination engine 1104 may determine the amount of power generated by each satellite of the constellation of satellites based on the incoming energy from the Sun and the set of peak values. In yet another embodiment, when the user 104 selects the set of solar panel parameters and the set of peak values associated with each satellite of the constellation of satellites satellite on the computing device 102 based on the interaction with the user interface rendered on the computing device 102, the determination engine may determine the amount of power generated by each satellite of the constellation of satellites based on the incoming energy from the Sun, the set of solar panel parameters, and the set of peak values.

The determination engine 1104 may further determine the amount of power consumed by each satellite of the constellation of satellites based on the power consumption data of the set of components in each mode. The power consumption data includes the amount of power consumed by each component of the set of components and the amount of power consumed by each mode of the plurality of modes.

The simulation engine 1106 may include suitable logic, circuitry, interfaces, and/or code, executable by the circuitry, that may perform one or more operations related to simulation of the power analysis of the satellite system. The simulation engine 1106 may further simulate the power analysis of the at least one satellite and each satellite of the constellation of satellites. Based on the amount of power generated and the amount of power consumed, the simulation engine 1106 may simulate the power analysis of the at least one satellite to determine the amount of power stored by the at least one satellite.

The simulation engine 1106 may repeat reception, determination, and simulation operations to iteratively determine the amount of power generated, the amount of power consumed, and the amount of power stored as the at least one satellite traverses through the respective orbit of the at least one satellite. In one embodiment, the amount of power generated, the amount of power consumed, and the amount of power stored by the at least one satellite may be iteratively determined at predefined time intervals. For example, the predefined time intervals may be ten seconds, one minute, and the like, such that the amount of power generated, the amount of power consumed, and the amount of power stored may be determined iteratively after every ten seconds, every one minute, and the like, respectively.

In another embodiment, the amount of power generated, the amount of power consumed, and the amount of power stored by the at least one satellite may be iteratively determined when the user 104 modifies at least one of the set of solar panel parameters, the set of peak values, the amount of power consumed by each component of the set of components, and the amount of power consumed by each mode of the plurality of modes of operation of the at least one satellite during the simulation of the power analysis. The user 104 may modify at least one of the set of solar panel parameters, the set of peak values, the amount of power consumed by each component of the set of components, and the amount of power consumed by each mode of the plurality of modes of operation of the at least one satellite based on the interaction with the user interface rendered on the computing device 102.

For example, each time when the user 104 modifies at least one of the set of solar panel parameters, the set of peak values, the amount of power consumed by each component of the set of components, and the amount of power consumed by each mode of the plurality of modes of operation of the at least one satellite, the amount of power generated, the amount of power consumed, and the amount of power stored are determined iteratively. Further, the simulation engine 1106 may iteratively store the data in the buffer 205 after performing the power analysis of the at least one satellite. The data includes the amount of power generated, the amount of power consumed, and the amount of power stored by the at least one satellite.

Based on the amount of power generated and the amount of power consumed, the simulation engine 1106 may simulate the power analysis of each satellite of the constellation of satellites in parallel to determine the amount of power stored by each satellite of the constellation of satellites. The simulation engine 1106 may repeat reception, determination, and simulation operations to iteratively determine the amount of power generated, the amount of power consumed, and the amount of power stored as each satellite of the constellation of satellites traverse through the respective orbit of each satellite of the constellation of satellites. In one embodiment, the amount of power generated, the amount of power consumed, and the amount of power stored by each satellite of the constellation of satellites may be iteratively determined at predefined time intervals, i.e., the simulation timestep. For example, the predefined time intervals may be ten seconds, one minute, and the like, such that the amount of power generated, the amount of power consumed, and the amount of power stored may be determined iteratively after every ten seconds, every one minute, and the like, respectively.

In another embodiment, the amount of power generated, the amount of power consumed, and the amount of power stored by each satellite of the constellation of satellites may be iteratively determined when the user 104 modifies at least one of the set of solar panel parameters, the set of peak values, the amount of power consumed by each component of the set of components, and the amount of power consumed by each mode of the plurality of modes of operation of each satellite of the constellation of satellites during the simulation of the power analysis. The user 104 may modify at least one of the set of solar panel parameters, the set of peak values, the amount of power consumed by each component of the set of components, and the amount of power consumed by each mode of the plurality of modes of operation of each satellite of the constellation of satellites based on the interaction with the user interface rendered on the computing device 102.

For example, each time when the user modifies at least one of the set of solar panel parameters, the set of peak values, the amount of power consumed by each component of the set of components, and the amount of power consumed by each mode of the plurality of modes of operation of each satellite of the constellation of satellites, the amount of power generated, the amount of power consumed, and the amount of power stored are determined iteratively. Further, the simulation engine 1106 may iteratively store the data in the buffer 205 after performing the power analysis of each satellite of the constellation of satellites in parallel. The data includes the amount of power generated, the amount of power consumed, and the amount of power stored by each satellite of the constellation of satellites.

According to an aspect of the present disclosure, the reception engine 1102 may further receive multiple sets of orientation parameters for multiple constellations of satellites from the buffer 205 and multiple sets of solar panel parameters, peak values, and power consumption data of a set of components in each mode of a plurality of modes of operation for the multiple constellations of satellites from the computing device 102. Based on the multiple sets of orientation parameters, solar panel parameters, peak values, and power consumption data of the set of components in each mode of the plurality of modes of operation, the simulation engine 1106 may simulate the link budget of the multiple constellations of satellites.

The user interface engine 1108 may include suitable logic, circuitry, interfaces, and/or code, executable by the circuitry, that may perform one or more operation related to displaying the visualization of the power analysis. The user interface engine 1108 may dynamically render the user interface, as the amount of power generated, the amount of power consumed, and the amount of power stored by the at least one satellite is iteratively determined. The user interface displays the visualization representing the amount of power generated, the amount of power consumed, and the amount of power stored by the at least one satellite as the at least one satellite traverses through the respective orbit of the at least one satellite.

The user interface engine 1108 may dynamically render the user interface, as the amount of power generated, the amount of power consumed, and the amount of power stored by each satellite of the constellation of satellites are iteratively determined. The user interface engine 1108 displays the visualization representing the amount of power generated, the amount of power consumed, and the amount of power stored by each satellite of the constellation of satellites as each satellite of the constellation of satellites traverse through a respective orbit of each satellite of the constellation of satellites. The data export subsystem 226 may receive the amount of power generated, the amount of power consumed, and the amount of power stored by the at least one satellite as power analysis data from the visualization subsystem 224 or the power analysis subsystem 218. Further, the data export subsystem 226 may be configured to export the power analysis data in a file. Examples of the file include, but are not limited to, a motion picture expert group (MPG) file, a MATLAB file, a comma separated value (CSV) and excel file, and a text file.

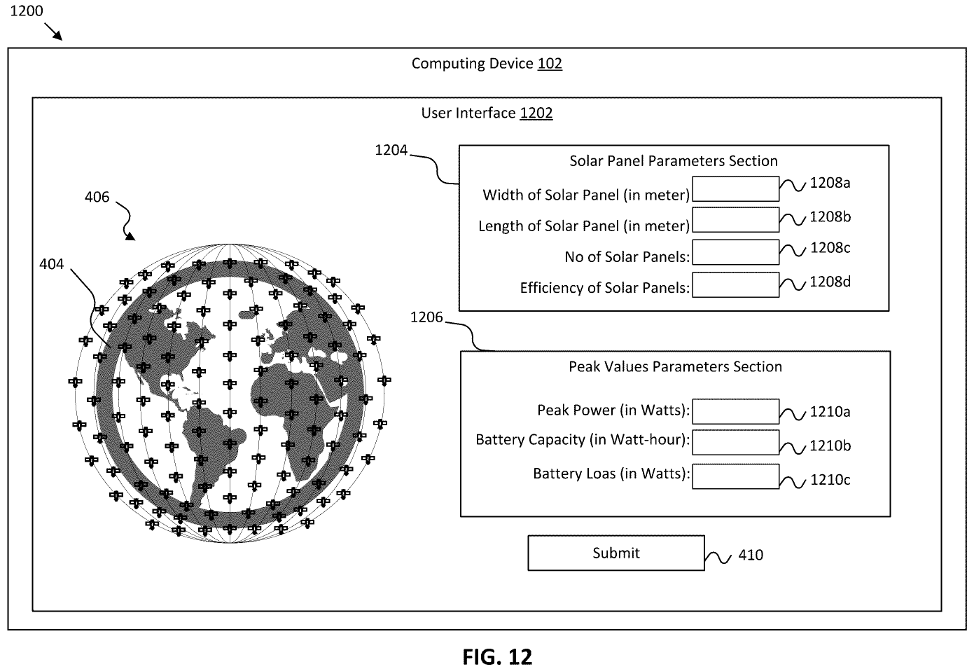

FIG. 12 is a block diagram 1200 that illustrates an exemplary user interface 1202 rendered on the computing device 102 in which aspects of the technology may be practiced. The user interface 1202 may include representation of the Earth 404, the satellite system 406, one or more input sections such as a solar panel parameters section 1204 and a peak values parameters section 1206, and one interactive interface element such as the interactive interface element 410.

In an embodiment, the application server 106 may be configured to render the user interface such as the user interface 1202 on the computing device 102. In one embodiment, the representation of the Earth 404 may correspond to 3D representation of the Earth or 2D plot of the Earth. The satellite system 406 may include the at least one satellite or may correspond to the constellation of satellites. The solar panel parameters section 1204 includes first through fourth input fields 1208a-1208d. The first input field 1208a may correspond to width of the solar panel in meter. The second input field 1208b may correspond to length of the solar panel in meter. The third input field 1208c may correspond to the number of solar panels. The fourth input field 1208d may correspond to the efficiency of the solar panels. The user 104 may input the set of solar panel parameters in the first through fourth input fields 1208a-1208d based on the interaction with the user interface 1202 rendered on the computing device 102.

The peak values parameters section 1206 includes first through third input fields 1210a-1210c. The first input field 1210a may correspond to the peak power of the solar panels in watts. The second input field 1210b may correspond to the maximum battery capacity in watt-hour. The third input field 1210c may correspond to the battery load in watts. The user 104 may input the set of peak values in the first through third input fields 1210a-1210c based on the interaction with the user interface 1202 rendered on the computing device 102.

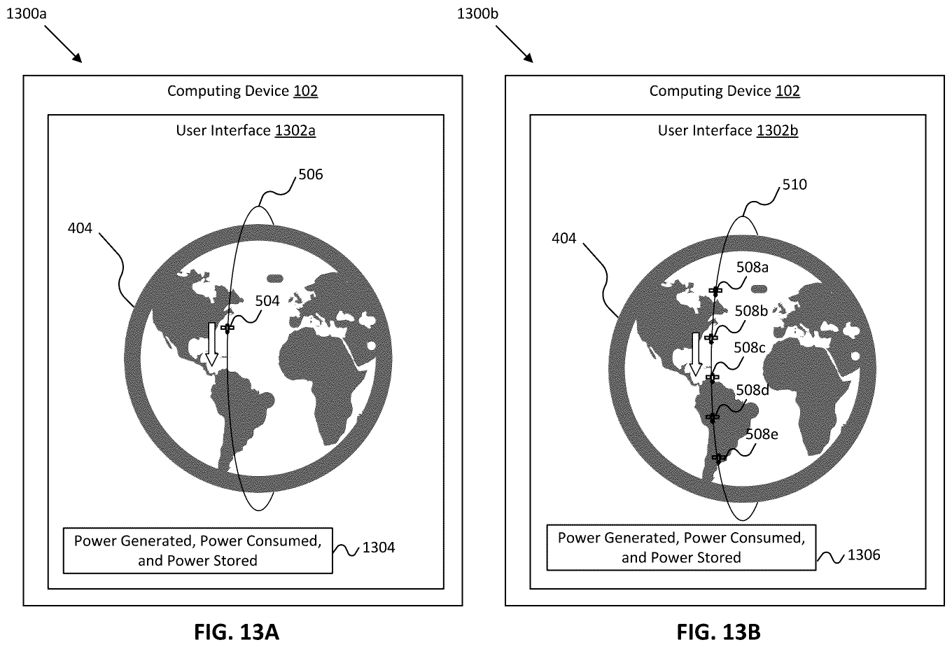

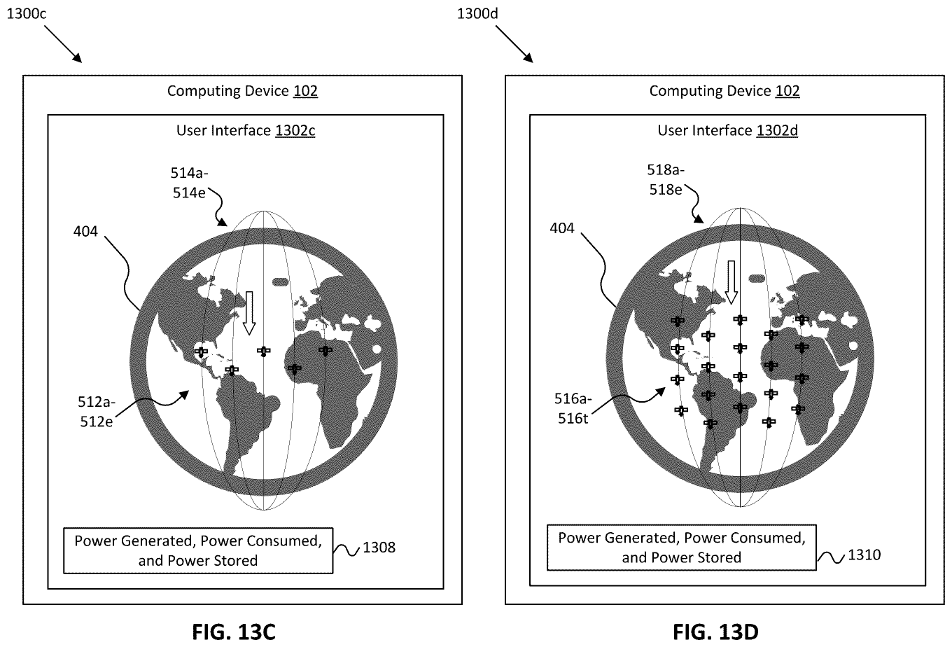

The interactive interface element 410 may correspond to the submit button that is selectable by the user 104 to trigger or initiate the simulation of the power analysis of the satellite system. When the user 104 selects the submit button, the computing device 102 may transmit the set of solar panel parameters and the set of peak values to the application server 106 and the application server 106 may trigger the simulation of the power analysis and render one of the user interfaces (shown later in FIGS. 13A-13D).

FIG. 13A is a diagram 1300a that represents an exemplary user interface 1202a rendered on the computing device 102 in which aspects of the technology may be practiced. The user interface 1202a presents the simulation of power analysis of the single satellite 504 of the satellite system 406 to iteratively determine an amount of power generated, an amount of power consumed, and an amount of power stored by the single satellite 504 as the single satellite 504 traverses through the orbital plane 506 and the Earth 404. The user interface 1302a may further include an output field 1304 that displays the amount of power generated, the amount of power consumed, and the amount of power stored by the single satellite 504 determined based on the simulation.

FIG. 13B is a diagram 1300b that represents an exemplary user interface 1302b rendered on the computing device 102 in which aspects of the technology may be practiced. The user interface 1302b presents the simulation of power analysis of each of the plurality of satellites 508a-508e of the satellite system 406 in parallel to iteratively determine an amount of power generated, an amount of power consumed, and an amount of power stored by the plurality of satellites 508a-508e as the plurality of satellites 508a-508e traverse through the single orbital plane 510 and the Earth 404. In an embodiment, the plurality of satellites 508a-508e may include five satellites that traverse through the single orbital plane 510. It may be understood by the person skilled in the art that the plurality of satellites 508a-508e may include any suitable number of satellites, without deviating from the scope of the present disclosure. The user interface 1302b may further include an output field 1306 that displays the amount of power generated, the amount of power consumed, and the amount of power stored by each of the plurality of satellites 508a-508e determined based on the simulation.

FIG. 13C is a diagram 1300c that represents an exemplary user interface 1302c rendered on the computing device 102 in which aspects of the technology may be practiced. The user interface 1302c presents the simulation of power analysis of each of the plurality of satellites 512a-512e of the satellite system 406 in parallel to iteratively determine an amount of power generated, an amount of power consumed, and an amount of power stored by the plurality of satellites 512a-512e as the plurality of satellites 512a-512e traverse through the plurality of orbital planes 514a-514e and the Earth 404. In an embodiment, the plurality of satellites 512a-512e may include five satellites and the plurality of orbital planes 514a-514e may include five planes where there may be one satellite per orbital plane. It may be understood by the person skilled in the art that the plurality of satellites 512a-512e may include any suitable number of satellites and the plurality of orbital planes 514a-514e may include any suitable number of orbital planes, without deviating from the scope of the present disclosure. The user interface 1302c may further include an output field 1308 that displays the amount of power generated, the amount of power consumed, and the amount of power stored by each of the plurality of satellites 512a-512e determined based on the simulation.

FIG. 13D is a diagram 1300d that represents an exemplary user interface 1302d rendered on the computing device 102 in which aspects of the technology may be practiced. The user interface 1302d presents the simulation of power analysis of each of the plurality of satellites 516a-516t of the satellite system 406 in parallel to iteratively determine an amount of power generated, an amount of power consumed, and an amount of power stored by the plurality of satellites 516a-516t as the plurality of satellites 516a-516t traverse through the plurality of orbital planes 518a-518e and the Earth 404. In an embodiment, the plurality of satellites 516a-516t may include twenty satellites and the plurality of orbital planes 518a-518e may include five planes where there may be four satellites per orbital plane. It may be understood by the person skilled in the art that the plurality of satellites 516a-516t may include any suitable number of satellites, without deviating from the scope of the present disclosure. It may be understood by the person skilled in the art that the plurality of orbital planes may include any suitable number of satellites, without deviating from the scope of the present disclosure. The user interface 1302d may further include an output field 1310 that displays the amount of power generated, the amount of power consumed, and the amount of power stored by each of the plurality of satellites 516a-516t determined based on the simulation.

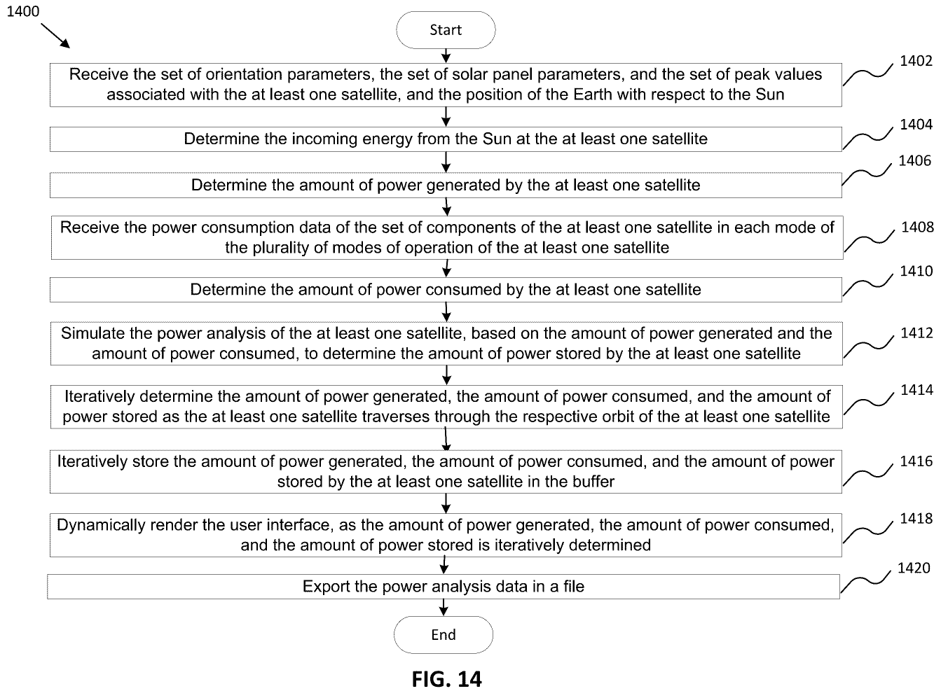

FIG. 14 illustrates a flow chart 1400 of a method for simulating the power analysis of the at least one satellite according to aspects of the disclosed technology.

At 1402, the parallel processor 202 may receive the set of orientation parameters, the set of solar panel parameters, and the set of peak values associated with the at least one satellite, and the position of the Earth with respect to the Sun. In an embodiment, the parallel processor 202 may receive the set of orientation parameters from the buffer 205. The set of orientation parameters may include the velocity and the position of the at least one satellite. The set of solar panel parameters includes at least one of the number of solar panels, the dimensions of the solar panels, the model of the solar panels, and the efficiency of the solar panels. The set of peak values includes at least one of the peak power of the solar panels, the maximum battery capacity, and the battery load. In an embodiment, the parallel processor 202 may receive the set of solar panel parameters and the set of peak values from the computing device 102 based on the interaction with the user interface 1202 rendered on the computing device 102.

At 1404, the parallel processor 202 may determine the incoming energy from the Sun at the at least one satellite based on the set of orientation parameters and the position of the Earth with respect to the Sun. At 1406, the parallel processor 202 may determine the amount of power generated by the at least one satellite based on the incoming energy from the Sun, the set of solar panel parameters, and the set of peak values.

At 1408, the parallel processor 202 may receive the power consumption data of the set of components of the at least one satellite in each mode of the plurality of modes of operation of the at least one satellite. The set of components includes the set of sensors of the at least one satellite. The plurality of modes comprise at least one of the launch and deployment mode, the commissioning phase mode, the nominal operations mode, the safe mode, the maneuvering mode, and the recovery and end of life mode. The power consumption data includes the amount of power consumed by each component of the set of components, and the amount of power consumed by each mode of the plurality of modes.

At 1410, the parallel processor 202 may determine the amount of power consumed by the at least one satellite based on the power consumption data of the set of components in each mode. At 1412, the parallel processor 202 may simulate the power analysis of the at least one satellite, based on the amount of power generated and the amount of power consumed, to determine the amount of power stored by the at least one satellite.

At 1414, the parallel processor 202 may iteratively determine the amount of power generated, the amount of power consumed, and the amount of power stored as the at least one satellite traverses through the respective orbit of the at least one satellite. The parallel processor 202 iteratively determines the amount of power generated, the amount of power consumed, and the amount of power stored by repeating 1402-1412. In one embodiment, the amount of power generated, the amount of power consumed, and the amount of power stored by the at least one satellite may be iteratively determined at the predefined time intervals. In another embodiment, the amount of power generated, the amount of power consumed, and the amount of power stored by the at least one satellite may be iteratively determined when the user 104 modifies at least one of the set of solar panel parameters, the set of peak values, the amount of power consumed by each component of the set of components, and the amount of power consumed by each mode of the plurality of modes of operation of the at least one satellite during the simulation of the power analysis.

At 1416, the parallel processor 202 may iteratively store the amount of power generated, the amount of power consumed, and the amount of power stored by the at least one satellite in the buffer 205 after performing the power analysis of the at least one satellite. At 1418, the parallel processor 202 may dynamically render the user interface, as the amount of power generated, the amount of power consumed, and the amount of power stored is iteratively determined. The user interface displays the visualization representing the amount of power generated, the amount of power consumed, and the amount of power stored by the at least one satellite as the at least one satellite traverses through the respective orbit of the at least one satellite. At 1420, the parallel processor 202 may export the power analysis data in the file. In one embodiment, the exported power analysis data may be utilized for further analysis and processing of satellite operations.

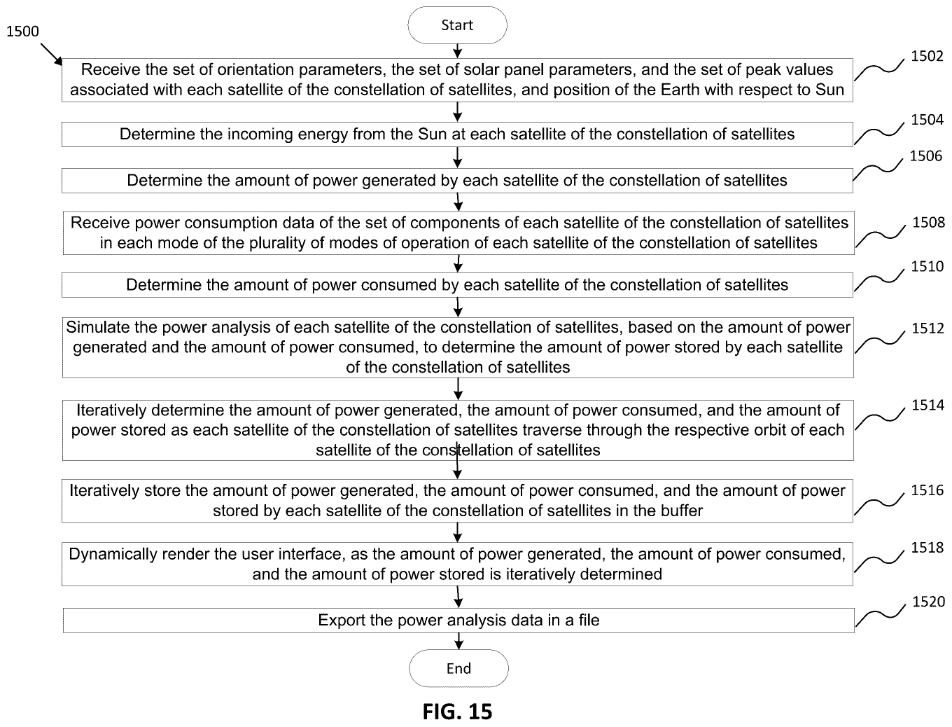

FIG. 15 illustrate a flow chart 1500 of a method for simulating the power analysis of each satellite of the constellation of satellites according to aspects of the disclosed technology.

At 1502, the parallel processor 202 may receive the set of orientation parameters, the set of solar panel parameters, and the set of peak values associated with each satellite of the constellation of satellites, and the position of the Earth with respect to the Sun. In an embodiment, the parallel processor 202 may receive the set of orientation parameters from the buffer 205.

At 1504, the parallel processor 202 may determine the incoming energy from the Sun at each satellite of the constellation of satellites based on the set of orientation parameters and the position of the Earth with respect to the Sun. At 1506, the parallel processor 202 may determine the amount of power generated by each satellite of the constellation of satellites based on the incoming energy from the Sun, the set of solar panel parameters, and the set of peak values.

At 1508, the parallel processor 202 may receive the power consumption data of the set of components of each satellite of the constellation of satellites in each mode of the plurality of modes of operation of each satellite of the constellation of satellites. The set of components includes the set of sensors of each satellite of the constellation of satellites. The plurality of modes comprise at least one of the launch and deployment mode, the commissioning phase mode, the nominal operations mode, the safe mode, the maneuvering mode, and the recovery and end of life mode. The power consumption data includes the amount of power consumed by each component of the set of components, and the amount of power consumed by each mode of the plurality of modes.

At 1510, the parallel processor 202 may determine the amount of power consumed by each satellite of the constellation of satellites based on the power consumption data of the set of components in each mode. At 1512, the parallel processor 202 may simulate the power analysis of each satellite of the constellation of satellites, based on the amount of power generated and the amount of power consumed, to determine the amount of power stored by each satellite of the constellation of satellites.

At 1514, the parallel processor 202 may iteratively determine the amount of power generated, the amount of power consumed, and the amount of power stored as each satellite of the constellation of satellites traverse through the respective orbit of each satellite of the constellation of satellites. The parallel processor 202 iteratively determines the amount of power generated, the amount of power consumed, and the amount of power stored by repeating 1502-1512. In one embodiment, the amount of power generated, the amount of power consumed, and the amount of power stored by each satellite of the constellation of satellites may be iteratively determined at the predefined time intervals. In another embodiment, the amount of power generated, the amount of power consumed, and the amount of power stored by each satellite of the constellation of satellites may be iteratively determined when the user 104 modifies at least one of the set of solar panel parameters, the set of peak values, the amount of power consumed by each component of the set of components, and the amount of power consumed by each mode of the plurality of modes of operation of each satellite of the constellation of satellites during the simulation of the power analysis.

At 1516, the parallel processor 202 may iteratively store the amount of power generated, the amount of power consumed, and the amount of power stored by each satellite of the constellation of satellites in the buffer 205 after performing the power analysis of each satellite of the constellation of satellites.

At 1518, the parallel processor 202 may dynamically render the user interface, as the amount of power generated, the amount of power consumed, and the amount of power stored is iteratively determined. The user interface displays the visualization representing the amount of power generated, the amount of power consumed, and the amount of power stored by each satellite of the constellation of satellites as each satellite of the constellation of satellites traverse through the respective orbit of each satellite of the constellation of satellites. At 1520, the parallel processor 202 may export the power analysis data in the file. In one embodiment, the exported power analysis data may be utilized for further analysis and processing of satellite operations.

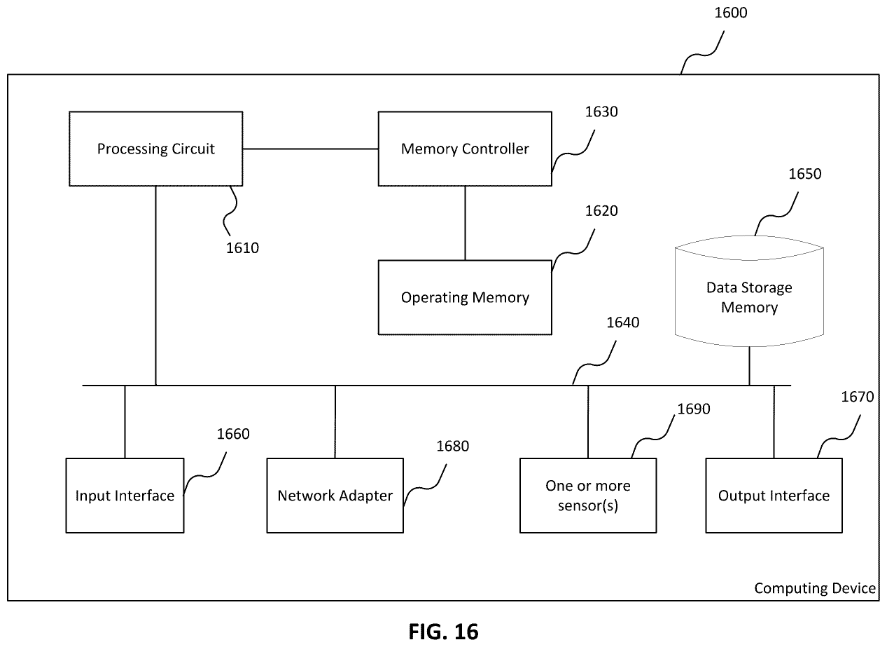

FIG. 16 is a diagram illustrating one example of computing device 1600 in which aspects of the technology may be practiced. Computing device 1600 may be virtually any type of general-purpose or specific-purpose computing device. For example, computing device 1600 may be an example of the parallel processor 202, a computing system or device (e.g., computing device 102) associated with the satellite as described above with reference to FIGS. 1-15.

As illustrated in FIG. 16, computing device 1600 includes processing circuit 1610, operating memory 1620, memory controller 1630, data storage memory 1650, input interface 1660, output interface 1670, and network adapter 1680. Each of these afore-listed components of computing device 1600 includes at least one hardware element.

Computing device 1600 includes at least one processing circuit 1610 configured to execute instructions, such as instructions for implementing the herein-described workloads, processes, or technology. Processing circuit 1610 may include a microprocessor, a microcontroller, a graphics processor, a coprocessor, a field-programmable gate array, a programmable logic device, a signal processor, or any other circuit suitable for processing data. The aforementioned instructions, along with other data (e.g., datasets, metadata, operating system instructions, etc.), may be stored in operating memory 1620 during run-time of computing device 1600. Operating memory 1620 may also include any of a variety of data storage devices/components, such as volatile memories, semi-volatile memories, random access memories, static memories, caches, buffers, or other media used to store run-time information. In one example, operating memory 1620 does not retain information when computing device 1600 is powered off. Rather, computing device 1600 may be configured to transfer instructions from a non-volatile data storage component (e.g., data storage memory 1650) to operating memory 1620 as part of a booting or other loading process. In some examples, other forms of execution may be employed, such as execution directly from data storage memory 1650.

Operating memory 1620 may include 4th generation double data rate (DDR4) memory, 3rd generation double data rate (DDR3) memory, other dynamic random access memory (DRAM), High Bandwidth Memory (HBM), Hybrid Memory Cube memory, 3D-staked memory, static random access memory (SRAM), magneto resistive random access memory (MRAM), pseudorandom random access memory (PSRAM), or other memory, and such memory may comprise one or more memory circuits integrated onto a DIMM, SIMM, SODIMM, Known Good Die (KGD), or other packaging. Such operating memory modules or devices may be organized according to channels, ranks, and banks. For example, operating memory devices may be coupled to processing circuit 1610 via memory controller 1630 in channels. One example of computing device 1600 may include one or two DIMMs per channel, with one or two ranks per channel. Operating memory within a rank may operate with a shared clock, and shared address and command bus. Also, an operating memory device may be organized into several banks where a bank can be thought of as an array addressed by row and column. Based on such an organization of operating memory, physical addresses within the operating memory may be referred to by a tuple of channel, rank, bank, row, and column.

Despite the above-discussion, operating memory 1620 specifically does not include or encompass communications media, any communications medium, or any signals per se.

Memory controller 1630 is configured to interface processing circuit 1610 to operating memory 1620. For example, memory controller 1630 may be configured to interface commands, addresses, and data between operating memory 1620 and processing circuit 1610. Memory controller 1630 may also be configured to abstract or otherwise manage certain aspects of memory management from or for processing circuit 1610. Although memory controller 1630 is illustrated as single memory controller separate from processing circuit 1610, in other examples, multiple memory controllers may be employed, memory controller(s) may be integrated with operating memory 1620, or the like. Further, memory controller(s) may be integrated into processing circuit 1610. These and other variations are possible.

In computing device 1600, data storage memory 1650, input interface 1660, output interface 1670, and network adapter 1680 are interfaced to processing circuit 1610 by bus 1640. Although, FIG. 16 illustrates bus 1640 as a single passive bus, other configurations, such as a collection of buses, a collection of point-to-point links, an input/output controller, a bridge, other interface circuitry, or any collection thereof may also be suitably employed for interfacing data storage memory 1650, input interface 1660, output interface 1670, or network adapter 1680 to processing circuit 1610.

In computing device 1600, data storage memory 1650 is employed for long-term non-volatile data storage. Data storage memory 1650 may include any of a variety of non-volatile data storage devices/components, such as non-volatile memories, disks, disk drives, hard drives, solid-state drives, or any other media that can be used for the non-volatile storage of information. However, data storage memory 1650 specifically does not include or encompass communications media, any communications medium, or any signals per se. In contrast to operating memory 1620, data storage memory 1650 is employed by computing device 1600 for non-volatile long-term data storage, instead of for run-time data storage.

Also, computing device 1600 may include or be coupled to any type of processor-readable media such as processor-readable storage media (e.g., operating memory 1620 and data storage memory 1650) and communication media (e.g., communication signals and radio waves). While the term processor-readable storage media includes operating memory 1620 and data storage memory 1650, the term “processor-readable storage media,” throughout the specification and the claims whether used in the singular or the plural, is defined herein so that the term “processor-readable storage media” specifically excludes and does not encompass communications media, any communications medium, or any signals per se. However, the term “processor-readable storage media” does encompass processor cache, Random Access Memory (RAM), register memory, and/or the like.

Computing device 1600 also includes input interface 1660, which may be configured to enable computing device 1600 to receive input from users or from other devices. In addition, computing device 1600 includes output interface 1670, which may be configured to provide output from computing device 1600.

In the illustrated example, computing device 1600 is configured to communicate with other computing devices or entities via network adapter 1680. Network adapter 1680 may include a wired network adapter, e.g., an Ethernet adapter, a Token Ring adapter, or a Digital Subscriber Line (DSL) adapter. Network adapter 1680 may also include a wireless network adapter, for example, a Wi-Fi adapter, a Bluetooth adapter, a ZigBee adapter, a Long-Term Evolution (LTE) adapter, SigFox, LoRa, Powerline, or a 5G adapter.

Although computing device 1600 is illustrated with certain components configured in a particular arrangement, these components and arrangement are merely one example of a computing device in which the technology may be employed. In other examples, data storage memory 1650, input interface 1660, output interface 1670, or network adapter 1680 may be directly coupled to processing circuit 1610, or be coupled to processing circuit 1610 via an input/output controller, a bridge, or other interface circuitry. Other variations of the technology are possible.

Some examples of computing device 1600 include at least one memory (e.g., operating memory 1620) adapted to store run-time data and at least one processor (e.g., processing circuit 1610) that is adapted to execute processor-executable code that, in response to execution, enables computing device 1600 to perform actions, where the actions may include, in some examples, actions for one or more methodologies or processes described herein, such as, methods of FIGS. 6A-6B, 10A-10B, 14, and 15, as described above.

The device or system of the present disclosure may additionally include one or more sensors 1690 to sense or gather data pertaining to the surrounding environment or operation of the device or system. Some exemplary sensors capable of being electronically coupled with the device or system of the present disclosure (either directly connected to the device or system of the present disclosure or remotely connected thereto) may include but are not limited to: accelerometers sensing accelerations experienced during rotation, translation, velocity/speed, location traveled, elevation gained; gyroscopes sensing movements during angular orientation and/or rotation, and rotation; magnetometers measuring the magnetic field experienced or observed by the satellite; star trackers capturing images of stars and comparing them to known star charts to precisely determine the satellite's orientation; sun sensor detecting and measuring the direction of the Sun; Earth sensor measuring the satellite's orientation and determines its attitude or position with respect to the Earth's surface; altimeters sensing barometric pressure, altitude change, terrain climbed, local pressure changes, submersion in liquid; impellers measuring the amount of fluid passing thereby; Global Positioning and GNSS sensors sensing location, elevation, distance traveled, velocity/speed; audio sensors sensing local environmental sound levels, or voice detection; Photo/Light sensors sensing ambient light intensity, ambient, Day/night, UV exposure; TV/IR sensors sensing light wavelength; Temperature sensors sensing machine or motor temperature, ambient air temperature, and environmental temperature; and Moisture Sensors sensing surrounding moisture levels.

The device or system of the present disclosure may include wireless communication logic coupled to sensors on the device or system. The sensors gather data and provide the data to the wireless communication logic. Then, the wireless communication logic may transmit the data gathered from the sensors to a remote device. Thus, the wireless communication logic may be part of a broader communication system, in which one or several devices or systems of the present disclosure may be networked together to report alerts and, more generally, to be accessed and controlled remotely. Depending on the types of transceivers installed in the device or system of the present disclosure, the system may use a variety of protocols (e.g., Wifi, ZigBee, MiWi, Bluetooth) for communication. In one example, each of the devices or systems of the present disclosure may have its own IP address and may communicate directly with a router or gateway. This would typically be the case if the communication protocol is WiFi.

In another example, a point-to-point communication protocol like MiWi or ZigBee is used. One or more of the device or system of the present disclosure may serve as a repeater, or the devices or systems of the present disclosure may be connected together in a mesh network to relay signals from one device or system to the next. However, the individual device or system in this scheme typically would not have IP addresses of their own. Instead, one or more of the devices or system of the present disclosure communicates with a repeater that does have an IP address, or another type of address, identifier, or credential needed to communicate with an outside network. The repeater communicates with the router or gateway.

In either communication scheme, the router or gateway communicates with a communication network, such as the Internet, although in some embodiments, the communication network may be a private network that uses transmission control protocol/internet protocol (TCP/IP) and other common Internet protocols but does not interface with the broader Internet, or does so only selectively through a firewall.

The system also allows individuals to access the device or system of the present disclosure for configuration and diagnostic purposes. In that case, the individual processors or microcontrollers of the device or system of the present disclosure may be configured to act as Web servers that use a protocol like hypertext transfer protocol (HTTP) to provide an online interface that can be used to configure the device or system. In some embodiments, the systems may be used to configure several devices or systems of the present disclosure at once. For example, if several devices or systems are of the same model and are in similar locations in the same location, it may not be necessary to configure the devices or systems individually. Instead, an individual may provide configuration information, including baseline operational parameters, for several devices or systems at once.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of technology disclosed herein may be implemented using hardware, software, or a combination thereof. When implemented in software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone may be utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. The functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic,” as used herein, includes but is not limited to hardware, firmware, software, and/or combinations of each to perform a function(s) or an action(s), and/or to cause a function or action from another logic, method, and/or system. For example, based on a desired application or needs, logic may include a software-controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected,” “attached” or “coupled” to another feature or element, it can be directly connected, attached, or coupled to the other feature or element or intervening features or elements may be present. In contrast, when a feature or element is referred to as being “directly connected,” “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly,” “downwardly,” “vertical,” “horizontal,” “lateral,” “transverse,” “longitudinal,” and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an example embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an example embodiment,” “an exemplary embodiment,” or “other embodiments,” or the like, are not necessarily all referring to the same embodiments. References in the specification to “an embodiment,” “one embodiment,” “some embodiments,” “one particular embodiment,” “an example embodiment,” “an exemplary embodiment,” or “other embodiments,” or the like, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

If this specification states a component, feature, structure, or characteristic “may,” “might,” or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment for an application for which it is intended. As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

In the foregoing description, certain terms have been used for brevity, clearness, and understanding. No unnecessary limitations are to be implied therefrom beyond the requirement of the prior art because such terms are used for descriptive purposes and are intended to be broadly construed.

The description and illustration of various embodiments of the disclosure are examples and the disclosure is not limited to the exact details shown or described. While various embodiments of the disclosed subject matter have been described above, it should be understood that they have been presented by way of example only, and not limitation. It will be understood by those skilled in the relevant art(s) that various changes in form and details may be made therein without departing from the spirit and scope of the embodiments as defined in the appended claims. Accordingly, the breadth and scope of the disclosed subject matter should not be limited by any of the above-described exemplary embodiments, but should be defined only in accordance with the following claims and their equivalents.

What is claimed:

1. A method for simulating orbit propagation of a satellite system comprising a constellation of satellites, the method comprising:
receiving an input indicating whether to simulate the orbit propagation for one of a single satellite of the constellation of satellites and a plurality of satellites of the constellation of satellites;
receiving a set of orbital parameters associated with each satellite of the constellation of satellites;
when the input indicates to simulate the orbit propagation for the single satellite:
simulating the orbit propagation of the single satellite to determine, based on the set of orbital parameters, a velocity and a position of the single satellite with respect to the Earth and the Sun, wherein the velocity and the position of the single satellite are iteratively determined by repeating the simulating of the orbit propagation of the single satellite as the single satellite traverses through a respective orbit of that single satellite;
when the input indicates to simulate the orbit propagation for the plurality of satellites:
simulating, via a parallel processor, the orbit propagation of each of the plurality of satellites in parallel to determine, based on the set of orbital parameters, a velocity and a position of each satellite of the plurality of satellites with respect to the Earth and the Sun, wherein the velocity and the position of each satellite of the plurality of satellites are iteratively determined by repeating the simulating of the orbit propagation for each satellite of the plurality of satellites as each satellite of the plurality of satellites traverses through a respective orbit of that satellite;
iteratively storing the velocity and the position of one of the single satellite and each of the plurality of satellites in a buffer after the simulating of the orbit propagation of one of the single satellite and the plurality of satellites; and
dynamically rendering a user interface to display a visualization representing the orbit propagation of one of the single satellite and the plurality of satellites based on the simulating of the orbit propagation of one of the single satellite and each of the plurality of satellites.

2. The method of claim 1, wherein the set of orbital parameters comprises at least one of an inclination angle, an angle between propagating planes, an altitude of the satellite, a number of propagating planes, an angle of a starting plane, a number of satellites in the constellation of satellites, a number of satellites per plane, a number of orbit period, a timestep per period, a simulation timestep, a beam angle, a day and time of launch, and a simulation period.

3. The method of claim 1, wherein the set of orbital parameters are input based on an interaction with the user interface rendered on a computing device.

4. The method of claim 3, wherein the velocity and the position are iteratively determined when the user modifies the set of parameters.

5. The method of claim 1, further comprising:
utilizing the velocity and the position of one of the single satellite and each of the plurality of satellites and a set of link budget parameters to simulate link budgets for one of the single satellite and the constellation of satellites.

6. The method of claim 1, further comprising:
utilizing the velocity and the position of one of the single satellite and each of the plurality of satellites and a set of power analysis parameters to simulate power analysis for one of the single satellite and the constellation of satellites.

7. The method of claim 1, further comprising:
utilizing the velocity and the position of one of the single satellite and each of the plurality of satellites and a set of light pollution parameters to simulate light pollution for one of the single satellite and the constellation of satellites.

8. The method of claim 1, further comprising:
utilizing the velocity and the position of one of the single satellite and each of the plurality of satellites and a set of orientation parameters to simulate controlling of an orientation of one of the single satellite and the constellation of satellites to stabilize one of the single satellite and the constellation of satellites.

9. The method of claim 1, further comprising:
utilizing the velocity and the position of one of the single satellite and each of the plurality of satellites and a set of heat transfer parameters to simulate heat transfer for one of the single satellite and the constellation of satellites.

10. The method of claim 1, wherein the visualization corresponds to at least one of:
a two-dimensional plot,
a three-dimensional model of the Earth, and
a two-dimensional contour.

11. A system for simulating orbit propagation of a satellite system comprising a constellation of satellites, the system comprising:
at least one hardware-based processor and memory, wherein the memory comprises processor-executable instructions encoded on a non-transient processor-readable media, wherein the processor-executable instructions, when executed by the at least one hardware-based processor, configure the system to:
receive an input indicating whether to simulate the orbit propagation for one of a single satellite of the constellation of satellites and a plurality of satellites of the constellation of satellites;
receive a set of orbital parameters associated with each satellite of the constellation of satellites;
when the input indicates to simulate the orbit propagation for the single satellite:
simulate the orbit propagation of the single satellite to determine, based on the set of orbital parameters, a velocity and a position of the single satellite with respect to the Earth and the Sun, wherein the velocity and the position of the single satellite are iteratively determined by repeating the simulating of the orbit propagation of the single satellite as the single satellite traverses through a respective orbit of that satellite;
when the input indicates to simulate the orbit propagation for the plurality of satellites:
simulate, via a parallel processor, the orbit propagation of each of the plurality of satellites in parallel to determine, based on the set of orbital parameters, a velocity and a position of each satellite of the plurality of satellites with respect to the Earth and the Sun, wherein the velocity and the position of each satellite of the plurality of satellites are iteratively determined by repeating the simulating of the orbit propagation for each satellite of the plurality of satellites as each satellite of the plurality of satellites traverse through a respective orbit of that satellite;
iteratively store the velocity and the position of one of the single satellite and each of the plurality of satellites in a buffer after the simulating of the orbit propagation of one of the single satellite and the plurality of satellites; and
dynamically render a user interface to display a visualization representing the orbit propagation of one of the single satellite and the plurality of satellites based on the simulating of the orbit propagation of one of the single satellite and each of the plurality of satellites.

12. The system of claim 11, wherein the set of orbital parameters comprises at least one of an inclination angle, an angle between propagating planes, an altitude of the satellite, a number of propagating planes, an angle of a starting plane, a number of satellites in the constellation of satellites, a number of satellites per plane, a number of orbit period, a timestep per period, a simulation timestep, a beam angle, a day and time of launch, and a simulation period.

13. The system of claim 11, wherein the set of orbital parameters are input based on an interaction with the user interface rendered on a computing device, and wherein the velocity and the position are iteratively determined when the user modifies the set of parameters.

14. The system of claim 11, wherein the processor-executable instructions, when executed by the at least one hardware-based processor, further configure the system to:
utilizing the velocity and the position of one of the single satellite and each of the plurality of satellites and a set of link budget parameters to simulate link budgets for one of the single satellite and the constellation of satellites.

15. The system of claim 11, wherein the processor-executable instructions, when executed by the at least one hardware-based processor, further configure the system to:
utilize the velocity and the position of one of the single satellite and each of the plurality of satellites and a set of power analysis parameters to simulate power analysis for one of the single satellite and the constellation of satellites.

16. The system of claim 11, wherein the processor-executable instructions, when executed by the at least one hardware-based processor, further configure the system to:
utilize the velocity and the position of one of the single satellite and each of the plurality of satellites and a set of light pollution parameters to simulate light pollution for one of the single satellite and the constellation of satellites.

17. The system of claim 11, wherein the processor-executable instructions, when executed by the at least one hardware-based processor, further configure the system to:
utilize the velocity and the position of one of the single satellite and each of the plurality of satellites and a set of orientation parameters to simulate controlling of an orientation of one of the single satellite and the constellation of satellites to stabilize one of the single satellite and the constellation of satellites.

18. The system of claim 11, wherein the processor-executable instructions, when executed by the at least one hardware-based processor, further configure the system to:
utilizing the velocity and the position of one of the single satellite and each of the plurality of satellites and a set of heat transfer parameters to simulate heat transfer for one of the single satellite and the constellation of satellites.

19. The system of claim 11, wherein the visualization corresponds to at least one of:
a two-dimensional plot,
a three-dimensional model of the Earth, and
a two-dimensional contour.

20. A non-transitory computer-readable medium storing a set of instructions for simulating orbit propagation of a satellite system comprising a constellation of satellites, the set of instructions comprising:
one or more instructions that, when executed by one or more processors of a device, cause the device to:
receive an input indicating whether to simulate the orbit propagation for one of a single satellite of the constellation of satellites and a plurality of satellites of the constellation of satellites;
receive a set of orbital parameters associated with each satellite of the constellation of satellites;
when the input indicates to simulate the orbit propagation for the single satellite:
simulate the orbit propagation of the single satellite to determine, based on the set of orbital parameters, a velocity and a position of the single satellite with respect to the Earth and the Sun, wherein the velocity and the position of the single satellite are iteratively determined by repeating the simulating of the orbit propagation of the single satellite as the single satellite traverses through a respective orbit of that single satellite;
when the input indicates to simulate the orbit propagation for the plurality of satellites:
simulate, via a parallel processor, the orbit propagation of each of the plurality of satellites in parallel to determine, based on the set of orbital parameters, a velocity and a position of each satellite of the plurality of satellites with respect to the Earth and the Sun, wherein the velocity and the position of each satellite of the plurality of satellites are iteratively determined by repeating the simulating of the orbit propagation for each satellite of the plurality of satellites as each satellite of the plurality of satellites traverse through a respective orbit of that satellite;
iteratively store the velocity and the position of one of the single satellite and each of the plurality of satellites in a buffer after the simulating of the orbit propagation of one of the single satellite and the plurality of satellites; and
dynamically render a user interface to display a visualization representing the orbit propagation of one of the single satellite and the plurality of satellites based on the simulating of the orbit propagation of one of the single satellite and each of the plurality of satellites.
